(19) United States
(12) Patent Application Publication
(10) Pub. No.: US 2026/0293244 A1
(43) Pub. Date: Sep. 24, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Shunsuke ASABA, Himeji Hyogo (JP); Hiroshi KONO, Himeji Hyogo (JP)

(21) Appl. No.: 19/389,728

(22) Filed: Nov. 14, 2025

(30) Foreign Application Priority Data
Mar. 18, 2025 (JP) 2025-044079

(51) Int. Cl. H10D 62/10; H10D 8/60; H10D 30/66; H10D 62/60; H10D 62/832; H10D 84/00

(52) U.S. Cl. CPC H10D 62/126; H10D 8/60; H10D 30/66; H10D 62/60; H10D 62/8325; H10D 84/146

(57) ABSTRACT

Semiconductor device includes: first electrode; second electrode; silicon carbide layer between first and second electrodes, having first face, and including first conductive first silicon carbide region including first region and second region in contact with first face, second conductive second silicon carbide region between first silicon carbide region and first face, second conductive third silicon carbide region spaced from second silicon carbide region in first direction, first conductive fourth silicon carbide region between second silicon carbide region and first face and in contact with first portion of first electrode, and second conductive fifth silicon carbide region provided between first and second regions and provided in first direction of first portion, first and second regions provided between second and third silicon carbide regions; and gate electrode facing first and second regions, and fifth silicon carbide region.

### CROSS-REFERENCE TO RELATED APPLICATION

This application is based upon and claims the benefit of priority from Japanese Patent Application No. 2025-044079, filed on Mar 18, 2025, the entire contents of which are incorporated herein by reference.

### FIELD

Embodiments described herein relate generally to a semiconductor device.

### BACKGROUND

Silicon carbide has excellent physical properties, such as a bandgap of 3 times that of silicon, a breakdown field strength of about 10 times that of silicon, and a thermal conductivity of about 3 times that of silicon. By using such characteristics, it is possible to realize a metal oxide semiconductor field effect transistor (MOSFET) that has a high breakdown voltage and low loss and that can operate at high temperature, for example.

When the MOSFET is in an on state, the load connected to the MOSFET may be short-circuited to reduce the load resistance. In this case, the MOSFET is short-circuited and a large current flows through the MOSFET. The time from when the MOSFET is short-circuited to when the MOSFET breaks down is referred to as short-circuit tolerance. From the viewpoint of improving reliability, it is desired to improve the short-circuit tolerance of the MOSFET.

### BRIEF DESCRIPTION OF THE DRAWINGS

FIG. 1 is a schematic cross-sectional view of a semiconductor device according to a first embodiment;

FIG. 2 is a schematic top view of the semiconductor device according to the first embodiment;

FIG. 3 is a schematic top view of the semiconductor device according to the first embodiment;

FIG. 4 is a schematic cross-sectional view of the semiconductor device according to the first embodiment;

FIG. 5 is a schematic cross-sectional view of the semiconductor device according to the first embodiment;

FIG. 6 is a schematic cross-sectional view of the semiconductor device according to the first embodiment;

FIG. 7 is an equivalent circuit diagram of the semiconductor device according to the first embodiment;

FIG. 8 is a schematic cross-sectional view of a semiconductor device according to a comparative example;

FIG. 9 is a schematic top view of the semiconductor device according to the comparative example;

FIG. 10 is a schematic top view of the semiconductor device according to the comparative example;

FIG. 11 is a diagram showing a current path when the semiconductor device according to the comparative example is turned on;

FIG. 12 is a diagram showing a current path when the semiconductor device according to the first embodiment is turned on;

FIG. 13 is a diagram showing a current path when the semiconductor device according to the first embodiment is turned on;

FIG. 14 is a diagram showing a current path when the semiconductor device according to the first embodiment is turned on;

FIG. 15 is a schematic cross-sectional view of a semiconductor device according to a modification example of the first embodiment;

FIG. 16 is a schematic top view of a semiconductor device according to the modification example of the first embodiment;

FIG. 17 is a schematic cross-sectional view of the semiconductor device according to the modification example of the first embodiment;

FIG. 18 is a schematic cross-sectional view of a semiconductor device according to a second embodiment;

FIG. 19 is a schematic top view of a semiconductor device according to the second embodiment;

FIG. 20 is a schematic top view of the semiconductor device according to the second embodiment;

FIG. 21 is a schematic cross-sectional view of the semiconductor device according to the second embodiment;

FIG. 22 is a schematic cross-sectional view of a semiconductor device according to a third embodiment;

FIG. 23 is a schematic top view of the semiconductor device according to the third embodiment;

FIG. 24 is a schematic top view of the semiconductor device according to the third embodiment; and

FIG. 25 is a schematic cross-sectional view of the semiconductor device according to the third embodiment.

### DETAILED DESCRIPTION

A semiconductor device of embodiments includes: a first electrode including a first portion; a second electrode; a silicon carbide layer provided between the first electrode and the second electrode, having a first face on a side of the first electrode and a second face on a side of the second electrode, and including a first silicon carbide region of a first conductive type including a first region in contact with the first face and a second region in contact with the first face, a second silicon carbide region of a second conductive type provided between the first silicon carbide region and the first face, a third silicon carbide region of a second conductive type provided between the first silicon carbide region and the first face and spaced from the second silicon carbide region in a first direction parallel to the first face, a fourth silicon carbide region of a first conductive type provided between the second silicon carbide region and the first face and in contact with the first portion, and a fifth silicon carbide region of a second conductive type provided between the second silicon carbide region and the third silicon carbide region, in contact with the second silicon carbide region and the third silicon carbide region, provided between the first region and the second region, in contact with the first region and the second region, provided between the first silicon carbide region and the first face, in contact with the first face, and provided in the first direction of the first portion, the first region and the second region being provided between the second silicon carbide region and the third silicon carbide region; a first gate electrode provided on a side of the first face of the silicon carbide layer and facing the first region, the second region, the second silicon carbide region, the third silicon carbide region, and the fifth silicon carbide region on the first face; and a gate insulating layer provided between the silicon carbide layer and the first gate electrode.

Hereinafter, embodiments will be described with reference to the diagrams. In addition, in the following description, the same or similar members and the like may be denoted by the same reference numerals, and the description of the members and the like once described may be omitted as appropriate.

In addition, in the following description, when there are notations of n⁺, n, n⁻, p⁺, p, and p⁻, these notations indicate the relative high and low of the impurity concentration in each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, the distance such as the width or depth of an impurity region can be calculated by, for example, SIMS. In addition, the distance such as the width or depth of the impurity region can be calculated from, for example, an SCM image or an image of a scanning electron microscope (SEM). In addition, the thickness and the like of the insulating layer can be measured on, for example, an image of SIMS, SEM, or a transmission electron microscope (TEM).

In addition, in this specification, the "p-type impurity concentration" of the p-type silicon carbide region means the net p-type impurity concentration obtained by subtracting the n-type impurity concentration of the region from the p-type impurity concentration of the region. In addition, the "n-type impurity concentration" of the n-type silicon carbide region means the net n-type impurity concentration obtained by subtracting the p-type impurity concentration of the region from the n-type impurity concentration of the region.

In addition, unless otherwise specified in this specification, the impurity concentration of a specific region means the maximum impurity concentration of the region.

### First Embodiment

A semiconductor device according to a first embodiment includes: a first electrode including a first portion; a second electrode; a silicon carbide layer provided between the first electrode and the second electrode, having a first face on a side of the first electrode and a second face on a side of the second electrode, and including a first silicon carbide region of a first conductive type including a first region in contact with the first face and a second region in contact with the first face, a second silicon carbide region of a second conductive type provided between the first silicon carbide region and the first face, a third silicon carbide region of a second conductive type provided between the first silicon carbide region and the first face and spaced from the second silicon carbide region in a first direction parallel to the first face, a fourth silicon carbide region of a first conductive type provided between the second silicon carbide region and the first face and in contact with the first portion, and a fifth silicon carbide region of a second conductive type provided between the second silicon carbide region and the third silicon carbide region, in contact with the second silicon carbide region and the third silicon carbide region, provided between the first region and the second region, in contact with the first region and the second region, provided between the first silicon carbide region and the first face, in contact with the first face, and provided in the first direction of the first portion, the first region and the second region being provided between the second silicon carbide region and the third silicon carbide region; a first gate electrode provided on a side of the first face of the silicon carbide layer and facing the first region, the second region, the second silicon carbide region, the third silicon carbide region, and the fifth silicon carbide region on the first face; and a gate insulating layer provided between the silicon carbide layer and the first gate electrode.

The semiconductor device according to the first embodiment is a planar gate type vertical MOSFET 100 using silicon carbide. The MOSFET 100 according to the first embodiment is, for example, a double implantation MOSFET (DIMOSFET) in which a body region and a source region are formed by ion implantation. In addition, the MOSFET 100 according to the first embodiment includes a Schottky Barrier Diode (SBD) as a built-in diode.

Hereinafter, a case where the first conductive type is n-type and the second conductive type is p-type will be described as an example. The MOSFET 100 is a vertical n-channel MOSFET having electrons as carriers.

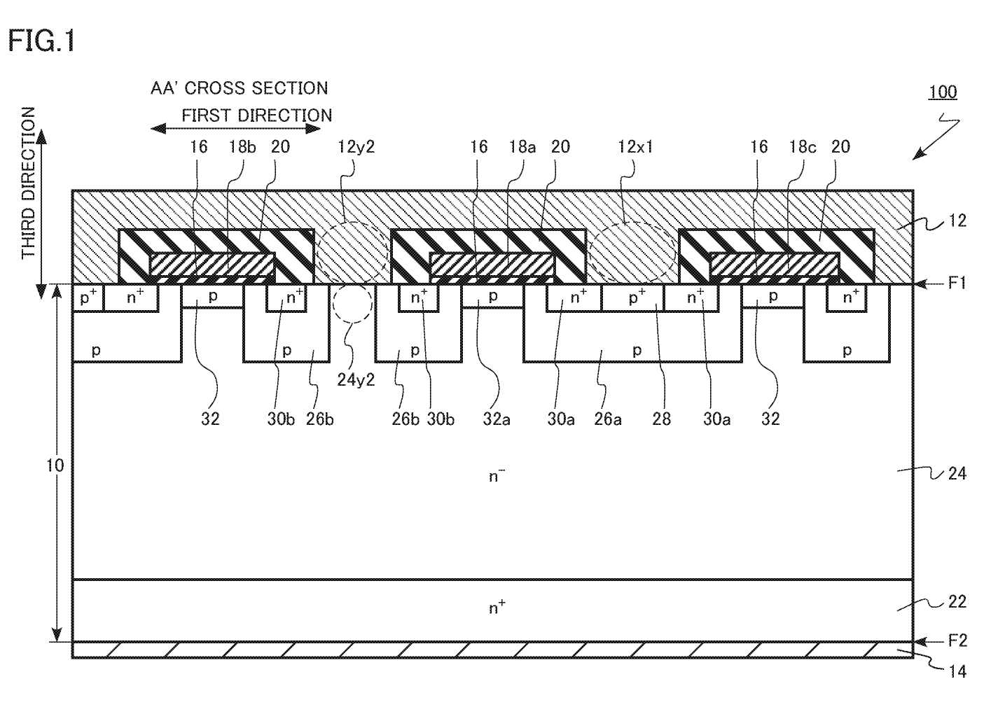

FIG. 1 is a schematic cross-sectional view of the semiconductor device according to the first embodiment.

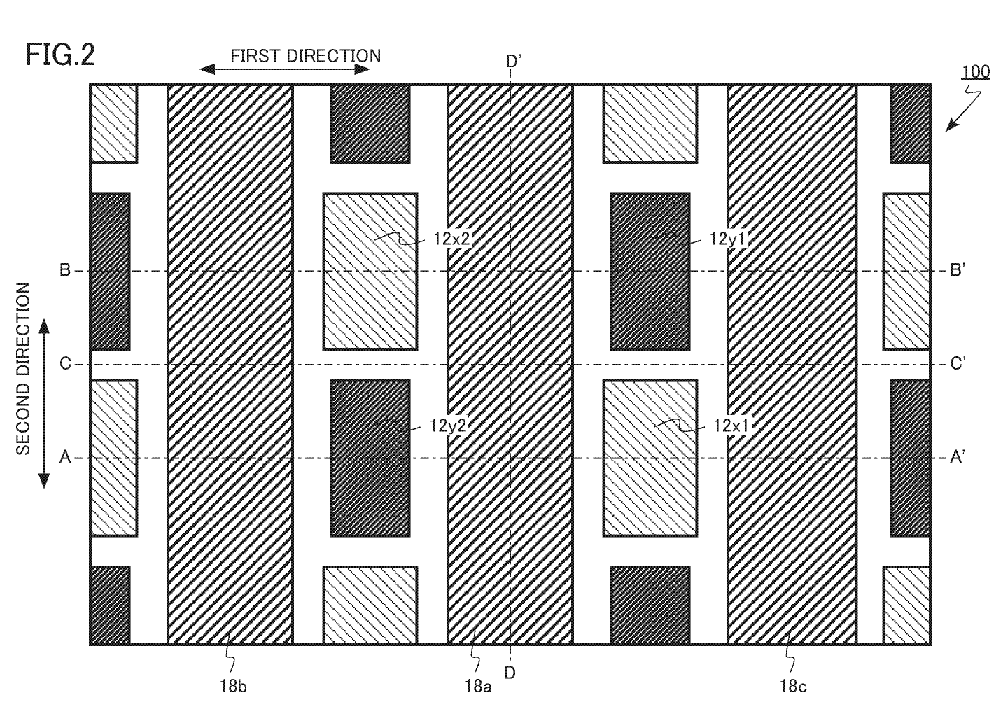

FIG. 2 is a schematic top view of the semiconductor device according to the first embodiment. FIG. 2 is a schematic diagram showing a pattern of a gate electrode and a source electrode on the top surface of a silicon carbide layer. FIG. 2 shows a pattern of a contact electrode portion and a diode electrode portion of the source electrode. FIG. 1 is a cross-sectional view taken along the line AA' of FIG. 2.

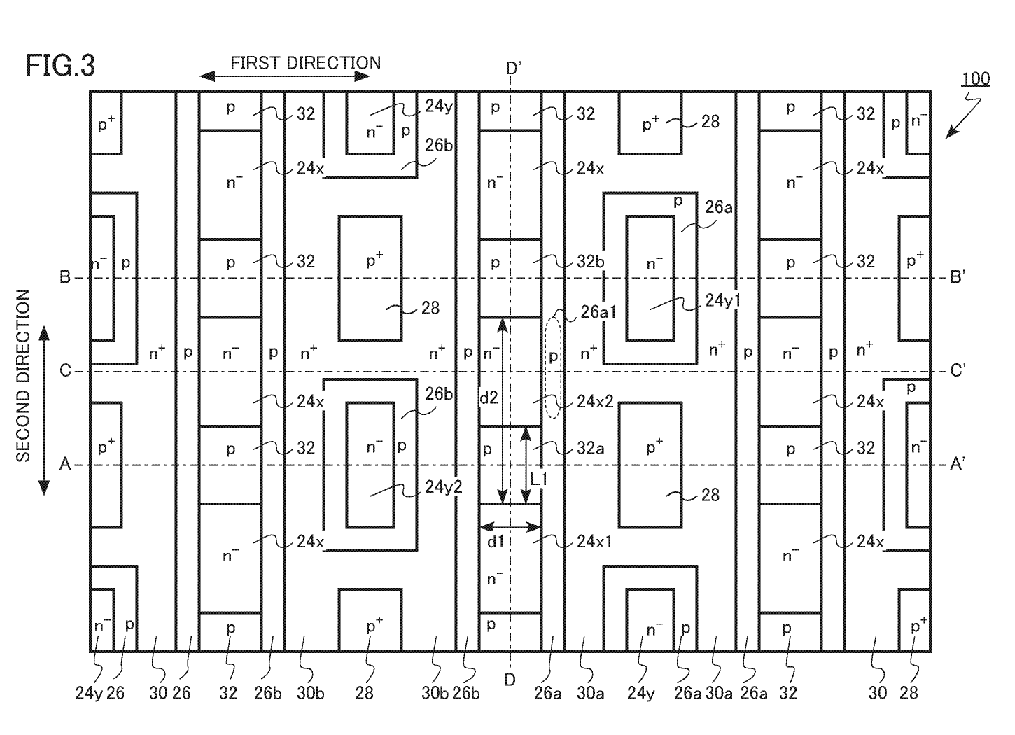

FIG. 3 is a schematic top view of the semiconductor device according to the first embodiment. FIG. 3 is a diagram showing a pattern of a semiconductor region on the surface of a silicon carbide layer. FIG. 1 is a cross- sectional view taken along the line AA' of FIG. 3.

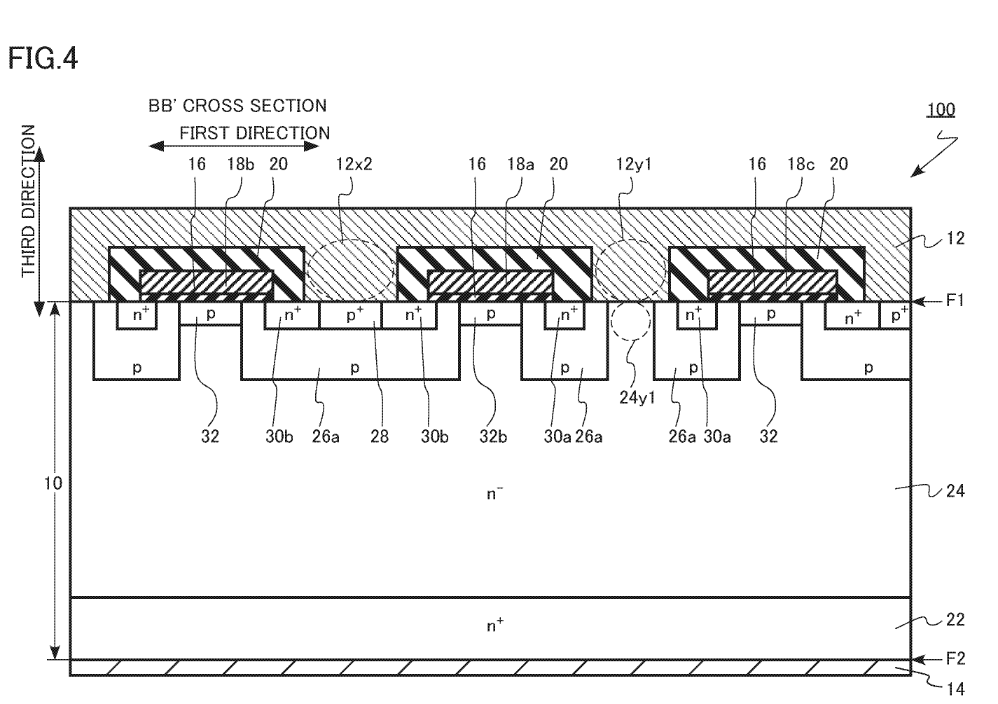

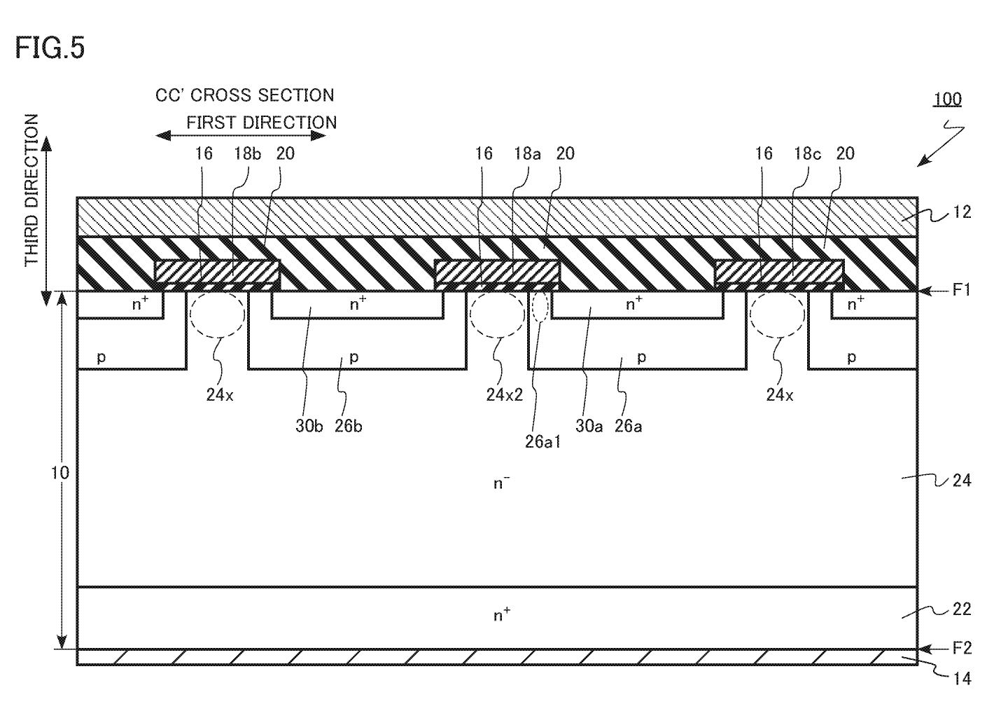

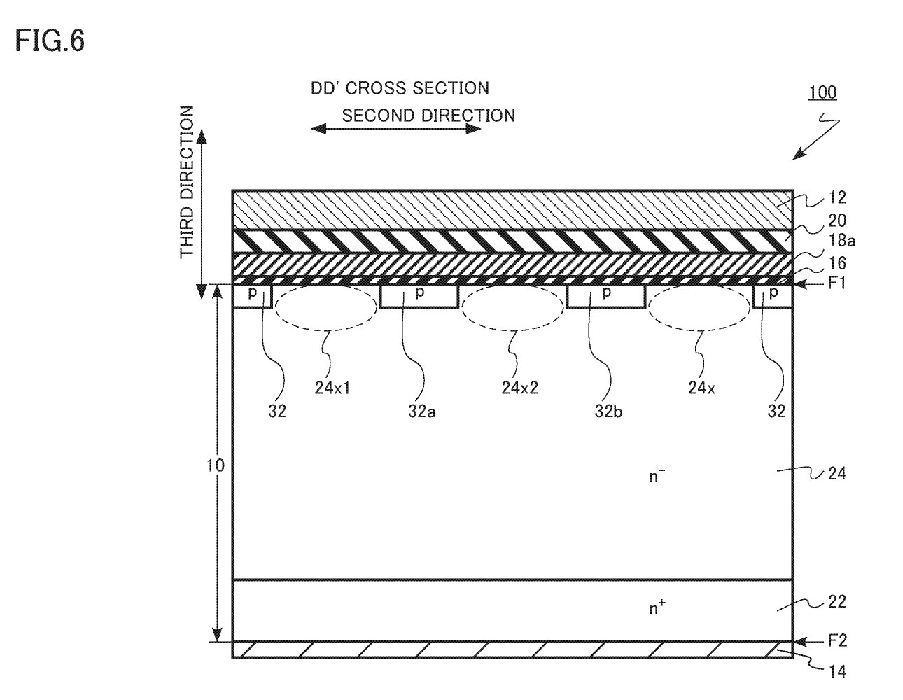

FIGS. 4, 5, and 6, are schematic cross-sectional views of the semiconductor device according to the first embodiment. FIG. 4 is a cross-sectional view taken along the line BB' of FIGS. 2 and 3. FIG. 5 is a cross-sectional view taken along the line CC' of FIGS. 2 and 3. FIG. 6 is a cross-sectional view taken along the line DD' of FIGS. 2 and 3.

The AA' cross section shown in FIG. 1 is an example of the first cross section. The BB' cross section shown in FIG. 4 is an example of the second cross section. The CC' cross section shown in FIG. 5 is an example of the third cross section.

The MOSFET 100 includes a silicon carbide layer 10, a source electrode 12 (first electrode), a drain electrode 14 (second electrode), a gate insulating layer 16, a gate electrode 18, and an interlayer insulating layer 20. The source electrode 12 includes a contact electrode portion 12x and a diode electrode portion 12y. The contact electrode portion 12x includes a first contact electrode portion 12x1 (first portion) and a second contact electrode portion 12x2. The diode electrode portion 12y includes a first diode electrode portion 12y1 (second portion) and a second diode electrode portion 12y2. The gate electrode 18 include a first gate electrode 18a, a second gate electrode 18b, and a third gate electrode 18c.

The silicon carbide layer 10 includes an n⁺-type drain region 22, an n⁻-type drift region 24 (first silicon carbide region), a p-type body region 26, a p⁺-type body contact region 28, an n⁺-type source region 30, and a p-type surface region 32. The p-type body region 26 includes a first body region of p-type 26a (second silicon carbide region) and a second body region of p-type 26b (third silicon carbide region). The first body region of p-type 26a includes a first channel portion 26a1 (fourth portion). The n⁺-type source region 30 includes a first source region of n⁺-type 30a (fourth silicon carbide region) and a second source region of n⁺-type 30b. The p-type surface region 32 includes a first surface region of p-type 32a (fifth silicon carbide region) and a second surface region of p-type 32b (sixth silicon carbide region).

The drift region 24 includes a JFET region 24x. The drift region 24 includes a first JFET region 24x1 (first region) and a second JFET region 24x2 (second region). In addition, JFET is an abbreviation for Junction Field Effect Transistor.

The drift region 24 includes a JBS region 24y. The JBS region 24y includes a first JBS region 24y1 (third region) and a second JBS region 24y2. In addition, JBS is an abbreviation for Junction Barrier Schottky.

The silicon carbide layer 10 is provided between the source electrode 12 and the drain electrode 14. The silicon carbide layer 10 is single crystal SiC. The silicon carbide layer 10 is, for example, 4H-SiC.

The silicon carbide layer 10 has a first face ("F1" in FIG. 1) and a second face ("F2" in FIG. 1). Hereinafter, the first face F1 may be referred to as a surface, and the second face F2 may be referred to as a back surface. The first face F1 is disposed on the source electrode 12 side of the silicon carbide layer 10. In addition, the second face F2 is disposed on the drain electrode 14 side of the silicon carbide layer 10. The first face F1 and the second face F2 face each other.

The “face” of the first face F1 and the second face F2 indicates, for example, an interface between a silicon carbide layer and an insulating layer or an interface between a silicon carbide layer and a metal.

Hereinafter, the “depth” means a depth in a direction toward the second face with the first face as a reference.

The first direction and the second direction are parallel to the first face F1. The second direction is perpendicular to the first direction. The third direction is perpendicular to the first direction and the second direction. The third direction is a direction connecting the first face F1 and the second face F2 to each other.

The first face F1 is, for example, a face inclined by an angle equal to or more than 0° and equal to or less than 8° with respect to the (0001) face. In addition, the second face F2 is, for example, a face inclined by an angle equal to or more than 0° and equal to or less than 8° with respect to the (000-1) face. The (0001) face is referred to as a silicon face. The (000-1) face is referred to as a carbon face.

The n⁺-type drain region 22 is provided on the back surface side of the silicon carbide layer 10. The drain region 22 contains, for example, nitrogen (N) as an n-type impurity. The n-type impurity concentration of the drain region 22 is, for example, equal to or more than 1 × 10¹⁸ cm⁻³ and equal to or less than 1 × 10²¹ cm⁻³.

The n⁻-type drift region 24 is provided between the drain region 22 and the first face F1. The n⁻-type drift region 24 is provided between the source electrode 12 and the drain electrode 14. The n⁻-type drift region 24 is provided between the gate electrode 18 and the drain electrode 14.

The n⁻-type drift region 24 is provided on the drain region 22. The drift region 24 contains, for example, nitrogen (N) as an n-type impurity. The n-type impurity concentration of the drift region 24 is lower than the n-type impurity concentration of the drain region 22. The n-type impurity concentration of the drift region 24 is, for example, equal to or more than 4 × 10¹⁴ cm⁻³ and equal to or less than 1 × 10¹⁷ cm⁻³. The thickness of the drift region 24 is, for example, equal to or more than 3 μm and equal to or less than 150 μm.

The n⁻-type drift region 24 includes the JFET region 24x. The drift region 24 includes the first JFET region 24x1 and the second JFET region 24x2.

The JFET region 24x is in contact with the first face F1. The JFET region 24x is provided between two body regions 26 adjacent to each other in the first direction. The JFET region 24x is in contact with two body regions 26 adjacent to each other in the first direction. The JFET region 24x is repeatedly provided in the second direction between two body regions 26 adjacent to each other in the first direction.

The first JFET region 24x1 is provided between the first body region 26a and the second body region 26b. The first JFET region 24x1 is in contact with the first body region 26a and the second body region 26b.

The second JFET region 24x2 is provided between the first body region 26a and the second body region 26b. The second JFET region 24x2 is in contact with the first body region 26a and the second body region 26b.

The second JFET region 24x2 is provided in the second direction with respect to the first JFET region 24x1. The second JFET region 24x2 is spaced from the first JFET region 24x1 in the second direction.

The drift region 24 includes the JBS region 24y. The JBS region 24y includes the first JBS region 24y1 and the second JBS region 24y2.

The JBS region 24y is in contact with the first face F1. The JBS region 24y is surrounded by the body region 26. For example, the first JBS region 24y1 is surrounded by the first body region 26a. For example, the second JBS region 24y2 is surrounded by the second body region 26b.

The JBS region 24y is in contact with the diode electrode portion 12y of the source electrode 12. For example, the first JBS region 24y1 is in contact with the first diode electrode portion 12y1. For example, the second JBS region 24y2 is in contact with the second diode electrode portion 12y2.

The p-type body region 26 is provided between the drift region 24 and the first face F1. The body region 26 extends in the second direction. The body region 26 functions as a channel region of the MOSFET 100.

The first body region 26a is provided between the drift region 24 and the first face F1. The second body region 26b is provided between the drift region 24 and the first face F1. The first body region 26a and the second body region 26b extend in the second direction. The second body region 26b is spaced from the first body region 26a in the first direction.

The body region 26 contains, for example, aluminum (Al) as a p-type impurity. The p-type impurity concentration of the body region 26 is, for example, equal to or more than 5 × 10¹⁶ cm⁻³ and equal to or less than 5 × 10¹⁹ cm⁻³.

The depth of the body region 26 is, for example, equal to or more than 500 nm and equal to or less than 900 nm.

The body region 26 is electrically connected to the source electrode 12. The body region 26 is fixed to the electric potential of the source electrode 12.

A part of the body region 26 is in contact with the first face F1. A part of the body region 26 faces the gate electrode 18. A part of the body region 26 becomes a channel region of the MOSFET 100. The gate insulating layer 16 is interposed between a part of the body region 26 and the gate electrode 18.

The p⁺-type body contact region 28 is provided between the body region 26 and the first face F1. The body contact region 28 is provided between the body region 26 and the contact electrode portion 12x of the source electrode 12.

The p-type impurity concentration of the body contact region 28 is higher than the p-type impurity concentration of the body region 26.

The body contact region 28 contains, for example, aluminum (Al) as a p-type impurity. The p-type impurity concentration of the body contact region 28 is, for example, equal to or more than 1 × 10¹⁹ cm⁻³ and equal to or less than 5 × 10²¹ cm⁻³.

The depth of the body contact region 28 is, for example, equal to or more than 80 nm and equal to or less than 500 nm.

The body contact region 28 is in contact with the source electrode 12. The body contact region 28 is electrically connected to the source electrode 12. The contact between the body contact region 28 and the source electrode 12 is, for example, an ohmic contact. The body contact region 28 is fixed to the electric potential of the source electrode 12.

The body contact region 28 is in contact with the contact electrode portion 12x of the source electrode 12.

The n⁺-type source region 30 is provided between the body region 26 and the first face F1. For example, the first source region 30a is provided between the first body region 26a and the first face F1. For example, the second source region 30b is provided between the second body region 26b and the first face F1.

The source region 30 contains, for example, phosphorus (P) or nitrogen (N) as an n-type impurity. The n-type impurity concentration of the source region 30 is higher than the n-type impurity concentration of the drift region 24.

The n-type impurity concentration of the source region 30 is, for example, equal to or more than 1 × 10¹⁹ cm⁻³ and equal to or less than 5 × 10²¹ cm⁻³. The depth of the source region 30 is smaller than the depth of the body region 26. The depth of the source region 30 is, for example, equal to or more than 80 nm and equal to or less than 200 nm.

The source region 30 is in contact with the source electrode 12. The source region 30 is electrically connected to the source electrode 12. The contact between the source region 30 and the source electrode 12 is, for example, an ohmic contact. The source region 30 is fixed to the electric potential of the source electrode 12.

The source region 30 is in contact with the contact electrode portion 12x of the source electrode 12. For example, the first source region 30a is in contact with the first contact electrode portion 12x1. For example, the second source region 30b is in contact with the second contact electrode portion 12x2.

The p-type surface region 32 is provided between the drift region 24 and the first face F1. The surface region 32 is in contact with the first face F1. The surface region 32 is provided between the drift region 24 and the gate electrode 18.

The surface region 32 is provided between two body regions 26 adjacent to each other in the first direction. The surface region 32 is in contact with two body regions 26 adjacent to each other.

The surface region 32 is repeatedly provided in the second direction between two body regions 26 adjacent to each other in the first direction. Between two body regions 26 adjacent to each other in the first direction, the surface region 32 and the JFET region 24x are alternately and repeatedly provided in the second direction.

A cross section that includes the first contact electrode portion 12x1 in contact with the first source region 30a of the source electrode 12 and is perpendicular to the first face F1 and parallel to the first direction is defined as a first cross section. The AA' cross section shown in FIG. 1 is an example of the first cross section.

The first surface region 32a is provided in the first direction of the first contact electrode portion 12x1. The first surface region 32a is provided between the drift region 24 and the first face F1 in the first cross section. The first surface region 32a is in contact with the first face F1 in the first cross section.

The first surface region 32a is provided between the drift region 24 and the first gate electrode 18a in the first cross section. The first surface region 32a is provided between the first body region 26a and the second body region 26b in the first cross section. The first surface region 32a is in contact with the first body region 26a and the second body region 26b in the first cross section.

The second surface region 32b is provided between the drift region 24 and the first face F1. The second surface region 32b is in contact with the first face F1. The second surface region 32b is provided between the drift region 24 and the first gate electrode 18a. The second surface region 32b is provided between the first body region 26a and the second body region 26b. The second surface region 32b is in contact with the first body region 26a and the second body region 26b.

The second surface region 32b is provided in the second direction of the first surface region 32a. The second surface region 32b is spaced from the first surface region 32a in the second direction. The second JFET region 24x2 is provided between the first surface region 32a and the second surface region 32b.

The first surface region 32a is in contact with the first JFET region 24x1 and the second JFET region 24x2. The second surface region 32b is in contact with the second JFET region 24x2.

The surface region 32 contains, for example, aluminum (Al) as a p-type impurity. The p-type impurity concentration of the surface region 32 is, for example, equal to or more than 5 × 10¹⁶ cm⁻³ and equal to or less than 5 × 10¹⁹ cm⁻³.

The first body region 26a includes the first channel portion 26a1 in contact with the gate insulating layer 16 and provided in the first direction of the second JFET 24x2. The p-type impurity concentration of a portion of the surface region 32 in contact with the gate insulating layer 16 is higher than the p-type impurity concentration of the first channel portion 26a1, for example.

A cross section that includes the second JFET 24x2 and is perpendicular to the first face F1 and parallel to the first direction is defined as a third cross section. The CC' cross section shown in FIG. 5 is an example of the third cross section. The first channel portion 26a1 is included in the third cross section.

The depth of the surface region 32 is, for example, smaller than the depth of the body region 26. The depth of the surface region 32 is, for example, smaller than the depth of the source region 30. The depth of the surface region 32 is, for example, equal to or more than 10 nm and equal to or less than 100 nm.

The depth of the first surface region 32a is, for example, smaller than the depth of the first body region 26a. The depth of the first surface region 32a is, for example, smaller than the depth of the first source region 30a. The depth of the surface region 32 is, for example, equal to or more than 10 nm and equal to or less than 100 nm.

A first length (L1 in FIG. 3) of the first surface region 32a in the second direction is, for example, larger than a first distance (d1 in FIG. 3) between the first body region 26a and the second body region 26b. The first length L1 is, for example, equal to or less than twice the first distance d1.

The first length (L1 in FIG. 3) of the first surface region 32a in the second direction is, for example, equal to or more than 20% and equal to or less than 50% of the second distance (d2 in FIG. 3) between the first JFET region 24x1 and the second surface region 32b.

The gate electrode 18 is provided on the first face F1 side of the silicon carbide layer 10. The gate electrode 18 extends in the second direction. A plurality of gate electrodes 18 are arranged in parallel with each other in the first direction. The plurality of gate electrodes 18 are spaced from each other in the first direction. The gate electrode 18 faces the drift region 24, the body region 26, the source region 30, and the surface region 32 on the first face F1.

The gate electrode 18 includes the first gate electrode 18a, the second gate electrode 18b, and the third gate electrode 18c.

The first gate electrode 18a extends in the second direction. The first gate electrode 18a faces the first JFET region 24x1, the second JFET region 24x2, the first body region 26a, the first source region 30a, the first surface region 32a, and the second surface region 32b on the first face F1.

The gate electrode 18 is a conductive layer. The gate electrode 18 is, for example, polycrystalline silicon containing p-type impurities or n-type impurities.

The gate insulating layer 16 is provided between the silicon carbide layer 10 and the gate electrode 18 on the first face F1. The gate insulating layer 16 is provided between the gate electrode 18 and each of the drift region 24, the body region 26, the source region 30, and the surface region 32 on the first face F1. The gate insulating layer 16 is provided, for example, between the first gate electrode 18a and each of the first JFET region 24x1, the second JFET region 24x2, the first body region 26a, the first source region 30a, the first surface region 32a, and the second surface region 32b.

The gate insulating layer 16 contains, for example, silicon oxide. The gate insulating layer 16 includes, for example, a silicon oxide layer. For example, an insulating material with a high dielectric constant can be applied to the gate insulating layer 16. In addition, for example, a stacked structure of a silicon oxide layer and an insulating layer with a high dielectric constant can also be applied to the gate insulating layer 16.

The thickness of the gate insulating layer 16 is, for example, equal to or more than 30 nm and equal to or less than 100 nm.

The interlayer insulating layer 20 is provided on the gate electrode 18. The interlayer insulating layer 20 is provided between the gate electrode 18 and the source electrode 12.

The interlayer insulating layer 20 electrically separates the gate electrode 18 and the source electrode 12 from each other. The interlayer insulating layer 20 contains, for example, silicon oxide. The interlayer insulating layer 20 is, for example, a silicon oxide layer.

The source electrode 12 is provided on the first face F1 side of the silicon carbide layer 10. The source electrode 12 is in contact with the silicon carbide layer 10. The source electrode 12 is in contact with the body contact region 28 and the source region 30.

The source electrode 12 includes the contact electrode portion 12x and the diode electrode portion 12y. The contact electrode portion 12x includes the first contact electrode portion 12x1 and the second contact electrode portion 12x2. The diode electrode portion 12y includes the first diode electrode portion 12y1 and the second diode electrode portion 12y2.

The contact electrode portion 12x is provided between two gate electrodes 18. For example, the first contact electrode portion 12x1 is provided between the first gate electrode 18a and the third gate electrode 18c. For example, the second contact electrode portion 12x2 is provided between the first gate electrode 18a and the second gate electrode 18b.

The contact electrode portion 12x is in contact with the source region 30 and the body contact region 28. For example, the first contact electrode portion 12x1 is in contact with the first source region 30a. For example, the second contact electrode portion 12x2 is in contact with the second source region 30b.

The diode electrode portion 12y is provided between two gate electrodes 18. For example, the first diode electrode portion 12y1 is provided between the first gate electrode 18a and the third gate electrode 18c. For example, the second diode electrode portion 12y2 is provided between the first gate electrode 18a and the second gate electrode 18b.

The diode electrode portion 12y is provided in the second direction of the contact electrode portion 12x. In addition, the diode electrode portion 12y is provided in the first direction of the contact electrode portion 12x with the gate electrode 18 interposed therebetween.

The contact electrode portion 12x and the diode electrode portion 12y are alternately and repeatedly arranged in the second direction between the same two gate electrodes 18. The contact electrode portion 12x and the diode electrode portion 12y are alternately and repeatedly arranged in the first direction with the gate electrode 18 interposed therebetween.

The diode electrode portion 12y is in contact with the JBS region 24y of the drift region 24. The diode electrode portion 12y functions as an anode electrode of the SBD.

The first diode electrode portion 12y1 is provided in the second direction of the first contact electrode portion 12x1. The first diode electrode portion 12y1 is in contact with the first JBS region 24y1 of the drift region 24.

The second diode electrode portion 12y2 is provided in the first direction of the first contact electrode portion 12x1 with the first gate electrode 18a interposed therebetween. The second diode electrode portion 12y2 is in contact with the second JBS region 24y2 of the drift region 24.

The surface region 32 is provided in the second direction of the diode electrode portion 12y. The surface region 32 is provided in a cross section that includes the diode electrode portion 12y of the source electrode 12 in contact with the JBS region 24y and is perpendicular to the first face F1 and parallel to the second direction.

In the first direction, the surface region 32 is provided between the contact electrode portion 12x and the diode electrode portion 12y. For example, the first surface region 32a is provided between the first contact electrode portion 12x1 and the second diode electrode portion 12y2. For example, the second surface region 32b is provided between the second contact electrode portion 12x2 and the first diode electrode portion 12y1.

The first JBS region 24y1 is provided in the second direction of the first contact electrode portion 12x1. The second surface region 32b is included in a second cross section that includes the first diode electrode portion 12y1 and is perpendicular to the first face F1 and parallel to the second direction. The BB' cross section shown in FIG. 4 is an example of the second cross section.

The source electrode 12 contains metal or metal silicide. A portion where the contact electrode portion 12x is in contact with the silicon carbide layer and a portion where the diode electrode portion 12y is in contact with the silicon carbide layer are formed of, for example, different materials. For example, a metal silicide is provided in a portion where the contact electrode portion 12x is in contact with the silicon carbide layer.

Between the contact electrode portion 12x and the source region 30 and between the contact electrode portion 12x and the body contact region 28, for example, an ohmic contact is formed.

Between the diode electrode portion 12y and the JBS region 24y, for example, there is a Schottky contact.

The drain electrode 14 is provided on the second face F2 side of the silicon carbide layer 10. The drain electrode 14 is provided on the second face F2 of the silicon carbide layer 10. The drain electrode 14 is in contact with the second face F2.

The drain electrode 14 contains, for example, a metal or a metal semiconductor compound.

The drain electrode 14 is electrically connected to the drain region 22. The drain electrode 14 is in contact with, for example, the drain region 22.

Next, the function and effect of the MOSFET 100 according to the first embodiment will be described.

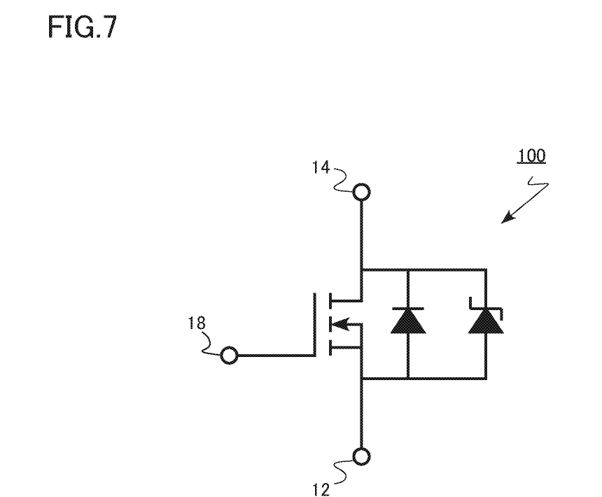

FIG. 7 is an equivalent circuit diagram of the semiconductor device according to the first embodiment. In the MOSFET 100, between the source electrode 12 and the drain electrode 14, a pn diode and an SBD are connected as built-in diodes in parallel to a transistor. The source electrode 12 is an anode of the SBD, and the drain electrode 14 is a cathode of the SBD.

For example, a case where the MOSFET 100 is used as a switching element connected to an inductive load is considered. When the MOSFET 100 is turned off, a voltage that is positive with respect to the drain electrode 14 may be applied to the source electrode 12 due to an induced current caused by an inductive load. In this case, a forward current flows through the built-in diode. This state is also referred to as a reverse conduction state.

If the MOSFET does not include an SBD, a forward current flows through the pn junction diode. The pn junction diode operates in a bipolar manner. When a freewheeling current is made to flow by using a pn junction diode that operates in a bipolar manner, a stacking fault grows in a silicon carbide layer due to the recombination energy of carriers. When the stacking fault grows in the silicon carbide layer, there arises a problem that the on-resistance of the MOSFET increases. The increase in the on-resistance of the MOSFET leads to a reduction in the reliability of the MOSFET.

The MOSFET 100 includes an SBD. A forward voltage (Vf) at which a forward current starts to flow through the SBD is lower than a forward voltage (Vf) of the pn junction diode. Therefore, a forward current flows through the SBD prior to the pn junction diode.

The forward voltage (Vf) of the SBD is, for example, equal to or more than 1.0 V and less than 2.0 V. The forward voltage (Vf) of the pn junction diode is, for example, equal to or more than 2.0 V and equal to or less than 3.0 V.

The SBD operates in a unipolar manner. Therefore, even if a forward current flows, no stacking fault grows in the silicon carbide layer 10 due to the recombination energy of carriers. Therefore, an increase in the on-resistance of the MOSFET 100 is suppressed. As a result, the reliability of MOSFET 100 is improved.

When the MOSFET is in an on state, the load connected to the MOSFET may be short-circuited to reduce the load resistance. In this case, the MOSFET is short-circuited and a large current flows through the MOSFET. The time from when the MOSFET is short-circuited to when the MOSFET breaks down is referred to as short-circuit tolerance. From the viewpoint of improving reliability, it is desired to improve the short-circuit tolerance of the MOSFET.

As in the MOSFET 100, even in a MOSFET in which the SBD is provided, it is desired to improve the short-circuit tolerance.

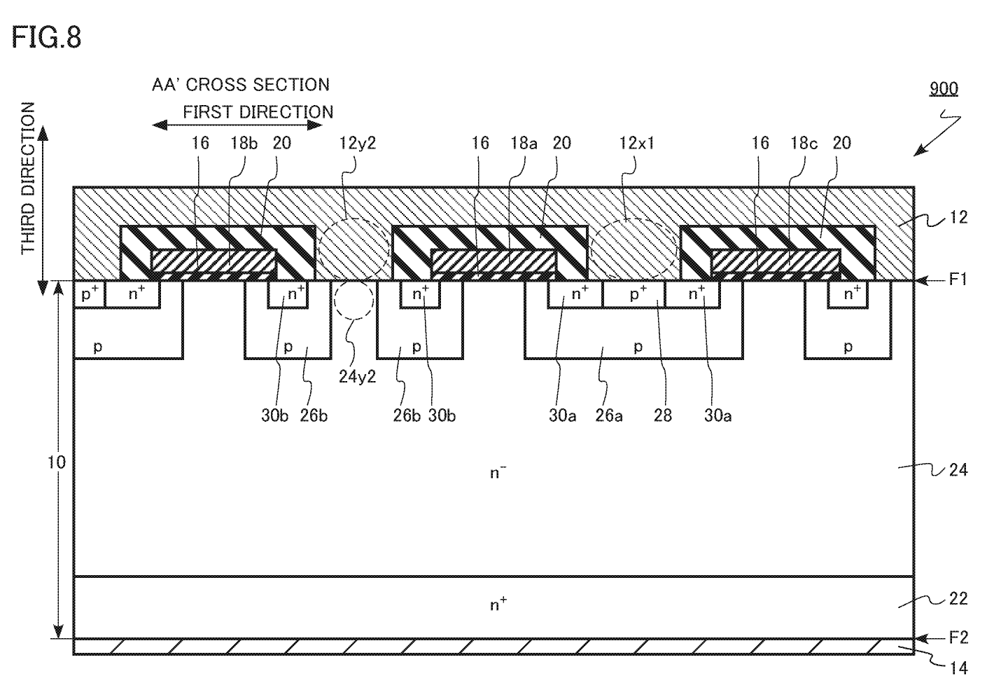

FIG. 8 is a schematic cross-sectional view of a semiconductor device according to a comparative example. FIG. 8 is a diagram corresponding to FIG. 1 in the first embodiment.

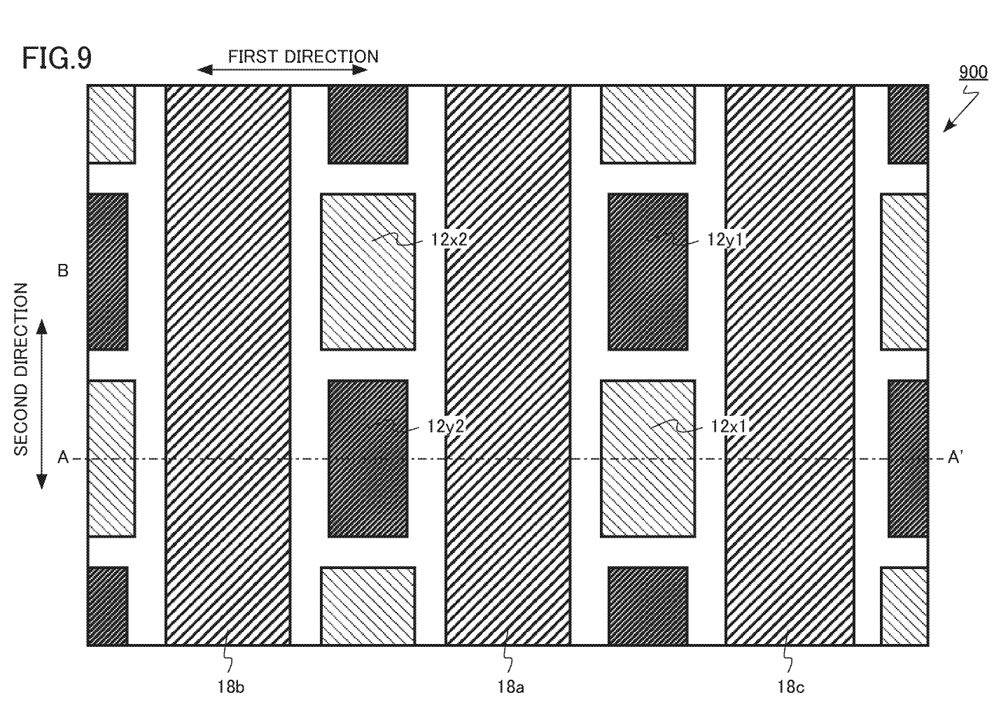

FIG. 9 is a schematic top view of the semiconductor device according to the comparative example. FIG. 9 is a schematic diagram showing a pattern of a gate electrode and a source electrode on the top surface of a silicon carbide layer. FIG. 9 shows a pattern of a contact electrode portion and a diode electrode portion of the source electrode. FIG. 8 is a cross-sectional view taken along the line AA' of FIG. 9. FIG. 9 is a diagram corresponding to FIG. 2 in the first embodiment.

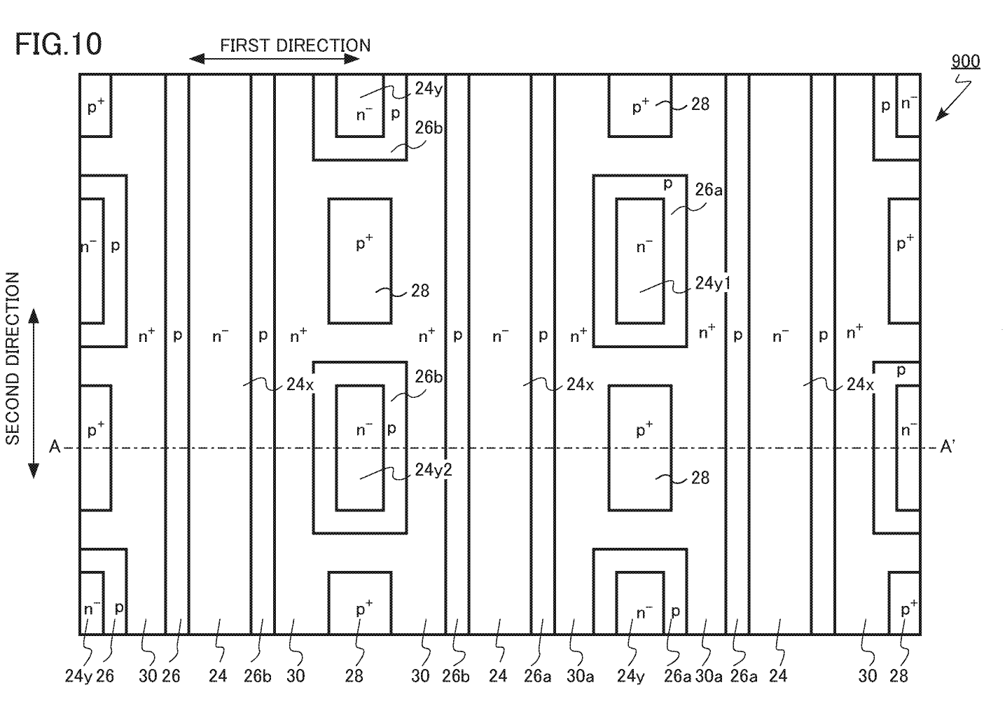

FIG. 10 is a schematic top view of the semiconductor device according to the comparative example. FIG. 10 is a diagram showing a pattern of a semiconductor region on the surface of a silicon carbide layer. FIG. 8 is a cross-sectional view taken along the line AA' of FIG. 10. FIG. 10 is a diagram corresponding to FIG. 3 in the first embodiment.

The semiconductor device according to the comparative example is a planar gate type vertical MOSFET 900 using silicon carbide. The MOSFET 900 according to the comparative example includes an SBD as a built-in diode. The MOSFET 900 according to the comparative example is different from the MOSFET 100 according to the first embodiment in that the silicon carbide layer 10 does not include the surface region 32.

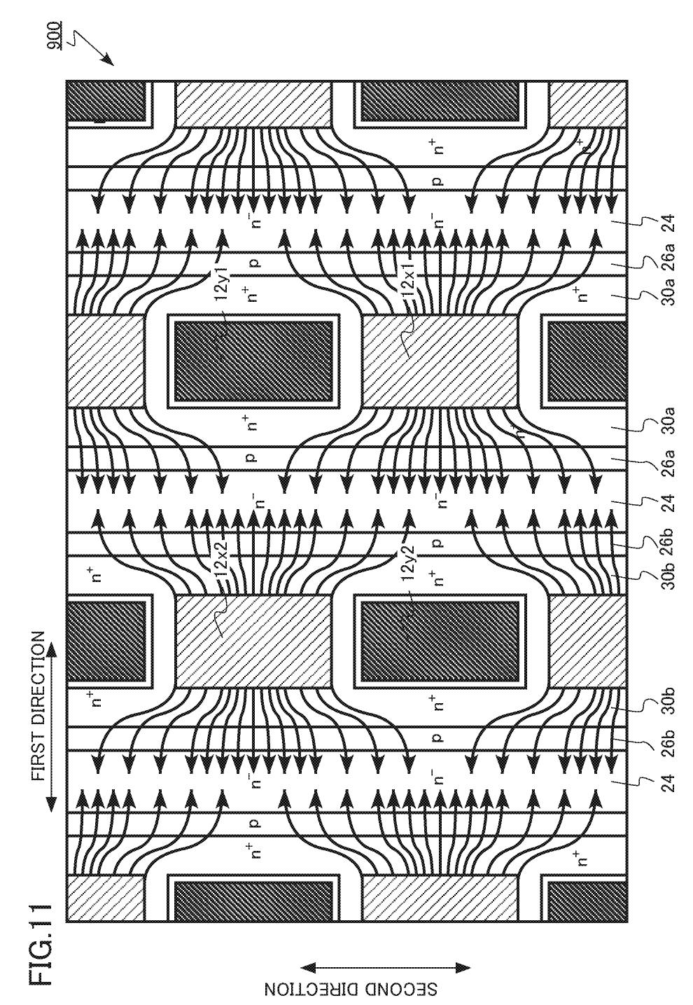

FIG. 11 is a diagram showing a current path when the semiconductor device according to the comparative example is turned on. FIG. 11 is a diagram in which the pattern of the contact electrode portion 12x and the diode electrode portion 12y is added to FIG. 10. FIG. 11 shows the flow of electrons that flow on the surface of the MOSFET 900 when the MOSFET 900 according to the comparative example is turned on. The direction of the current flow is opposite to that of the arrow in FIG. 11.

As shown in FIG. 11, when the MOSFET 900 is turned on in the normal state, electrons flow from the contact electrode portion 12x to the surface of the drift region 24 through the surface of the body region 26 in which a channel is formed. As shown in FIG. 11, in particular, the density of the electron flow increases in a portion close to the contact electrode portion 12x.

Even when the MOSFET 900 is short-circuited, electrons flow through a path similar to that shown in FIG. 11. When the MOSFET 900 is short-circuited, the resistance of the load connected to the MOSFET 900 is reduced. For this reason, a large number of electrons flow through the MOSFET 900, causing the MOSFET 900 to generate heat. If the short-circuit state continues for a long time, the MOSFET 900 breaks down due to heat generation.

When the MOSFET 900 is short-circuited, the density of the electron flow increases in the drift region 24 close to the contact electrode portion 12x and having a high electrical resistance, resulting in a particularly large amount of heat generation. Therefore, there is a risk that the MOSFET 900 may break down in a portion close to the contact electrode portion 12x.

In addition, in the MOSFET 900, the diode electrode portion 12y is provided adjacent to the contact electrode portion 12x in the first direction. In other words, the diode electrode portion 12y is provided in the first direction of the contact electrode portion 12x with the drift region 24 interposed therebetween. For example, the second diode electrode portion 12y2 is provided adjacent to the first contact electrode portion 12x1 in the first direction.

Therefore, in the MOSFET 900, there is a risk that the SBD adjacent to the drift region 24, which generates a particularly large amount of heat, may break down due to heat generation.

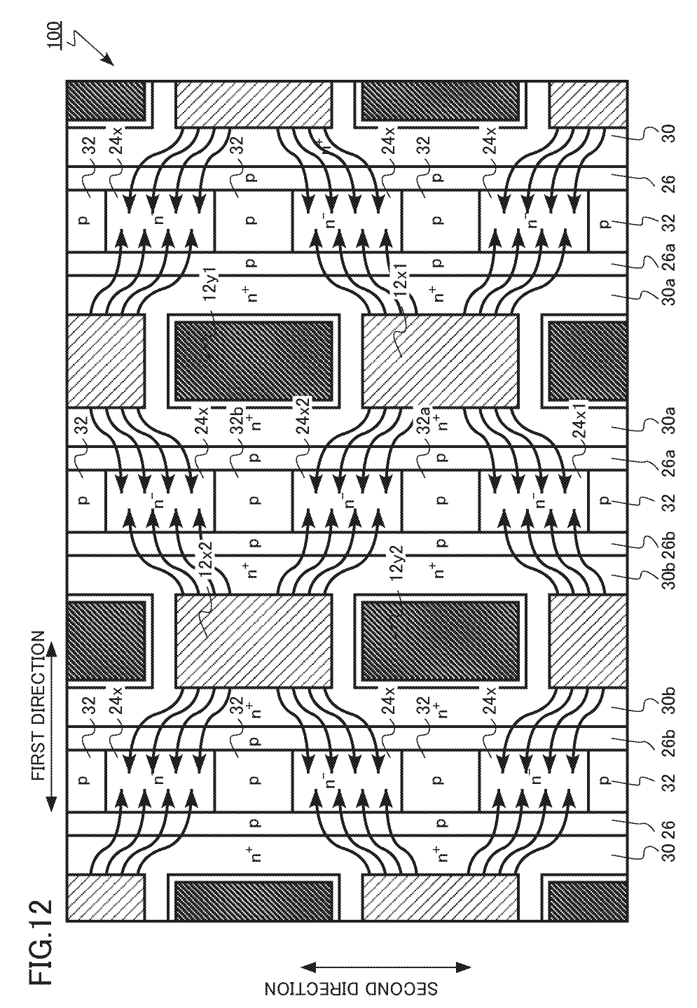

FIG. 12 is a diagram showing a current path when the semiconductor device according to the first embodiment is turned on. FIG. 12 is a diagram in which the pattern of the contact electrode portion 12x and the diode electrode portion 12y is added to FIG. 3. FIG. 12 shows the flow of electrons that flow on the surface of the MOSFET 100 when the MOSFET 100 according to the first embodiment is turned on.

As shown in FIG. 12, when the MOSFET 100 is turned on in the normal state, electrons flow from the contact electrode portion 12x to the surface of the drift region 24 through the surface of the body region 26 in which a channel is formed. As shown in FIG. 12, in the MOSFET 100, the p-type surface region 32 is provided on the surface of the n-type drift region 24. For this reason, electrons flowing from the contact electrode portion 12x to the surface of the drift region 24 bypass the surface region 32. Therefore, compared to the MOSFET 900 according to the comparative example, the density of the electron flow in a portion close to the contact electrode portion 12x decreases.

Even when the MOSFET 100 is short-circuited, electrons flow through a path similar to that shown in FIG. 12. When the MOSFET 100 is short-circuited, the density of the electron flow in the drift region 24 close to the contact electrode portion 12x decreases, so that the amount of heat generated is reduced compared to the MOSFET 900 according to the comparative example. Therefore, breakdown of the MOSFET 100 is suppressed. As a result, the short-circuit tolerance of the MOSFET 100 is improved.

In addition, in the MOSFET 100, since the amount of heat generated in the drift region 24 close to the contact electrode portion 12x is reduced, breakdown caused by heat generated in the SBD adjacent to the contact electrode portion 12x in the first direction is suppressed.

In the MOSFET 100, the surface region 32 is provided in the drift region 24, thereby limiting the path through which electrons flow. When the path through which electrons flow in a MOSFET is limited to reduce the flow of electrons in a short-circuit state and improve the short-circuit tolerance, there is a concern that the flow of electrons when the MOSFET is turned on in the normal state may decrease. In other words, when attempting to reduce the short-circuit current in a short-circuit state, there is a concern that the on-current in the normal state may decrease. In other words, there is a trade-off between improving the short-circuit tolerance and suppressing the decrease in on-current.

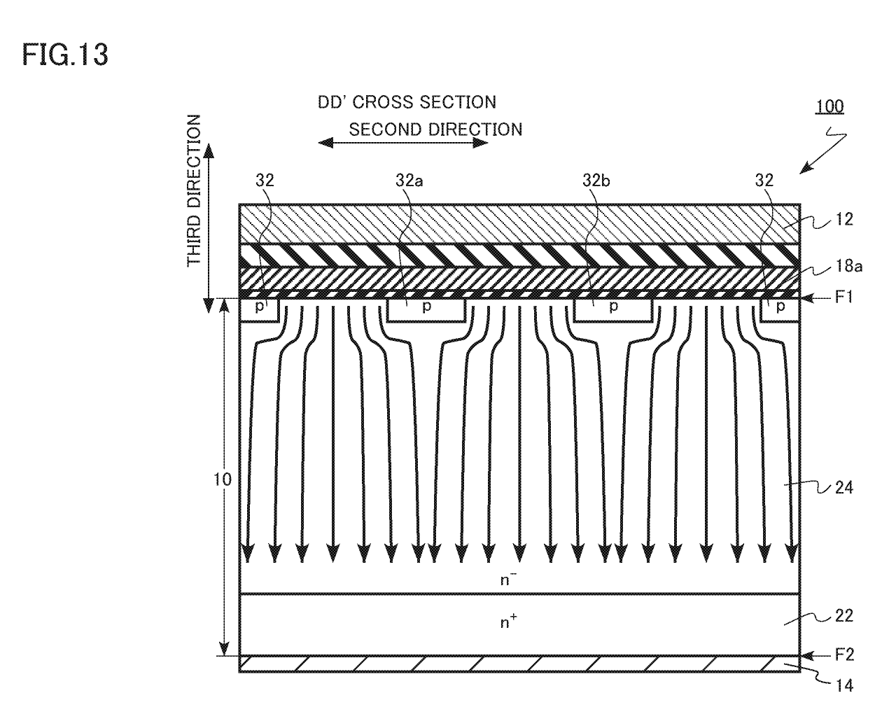

FIG. 13 is a diagram showing a current path when the semiconductor device according to the first embodiment is turned on. FIG. 13 is a diagram corresponding to FIG. 6. FIG. 13 shows the flow of electrons that flow through the drift region 24 of the MOSFET 100 when the MOSFET 100 according to the first embodiment is turned on in the normal state.

Electrons that have flowed from the body region 26 to the surface of the drift region 24 bypassing the surface region 32 on the surface of the silicon carbide layer 10 as shown in FIG. 12 flow around the bottom of the surface region 32 and flow toward the drain electrode 14 as shown in FIG. 13. On the surface of the silicon carbide layer 10, the path through which electrons flow is limited by the surface region 32. However, the path through which electrons flow is expanded by flowing around the bottom of the surface region 32. Therefore, the decrease in on-current is suppressed.

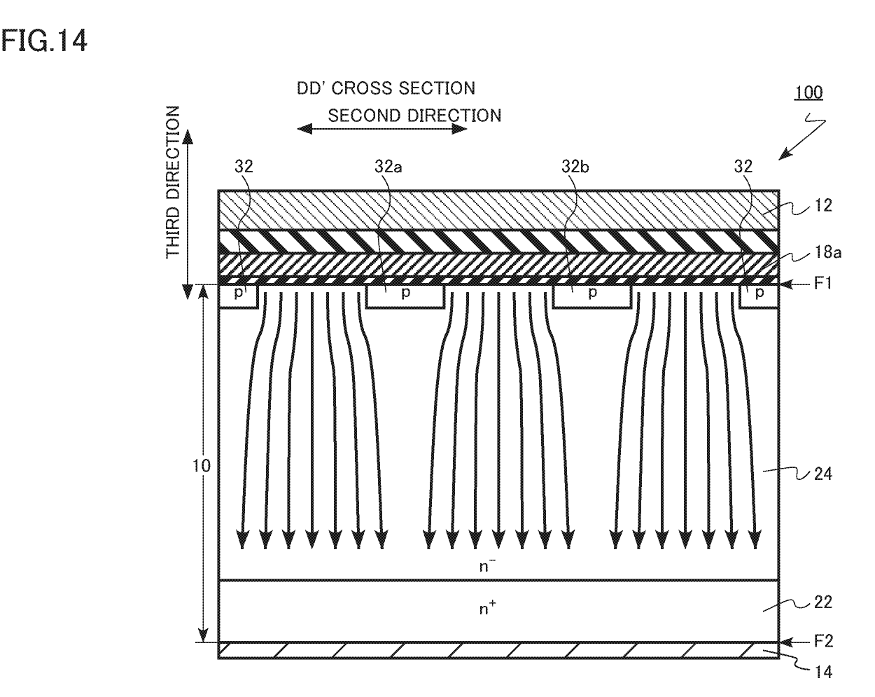

FIG. 14 is a diagram showing a current path when the semiconductor device according to the first embodiment is turned on. FIG. 14 is a diagram corresponding to FIG. 6. FIG. 14 shows the flow of electrons that flow through the drift region 24 of the MOSFET 100 when the MOSFET 100 according to the first embodiment is turned on in a short-circuit state.

As shown in FIG. 14, the amount of electrons flowing around the bottom of the surface region 32 in a short-circuit state is reduced compared to that in the normal state shown in FIG. 13. The reason why the amount of electrons flowing around the bottom of the surface region 32 in a short-circuit state is reduced is believed to be as follows.

In a short-circuit state, when electrons flow around the bottom of the surface region 32, the density of the electron flow at the corners of the bottom of the surface region 32 increases, and the amount of heat generated at the corners of the bottom of the surface region 32 increases. Since the n-type impurity concentration of the drift region 24 is low, the temperature dependence of the electrical resistance change is large. That is, as the temperature increases, the electrical resistance increases rapidly. In a short-circuit state, since the amount of heat generated at the corners of the bottom of the surface region 32 increases, the electrical resistance at the corners of the bottom of the surface region 32 increases. For this reason, it is believed that the flow of electrons around the bottom of the surface region 32 is suppressed compared to the normal state.

In the MOSFET 100 according to the first embodiment, the path of electron flow changes between the normal state and the short-circuit state, so that the rate of reduction in on-current in the normal state due to providing the surface region 32 can be made smaller than the rate of reduction in short-circuit current in the short-circuit state, as compared to the MOSFET 900 according to the comparative example. Therefore, the trade-off between improving the short-circuit tolerance and suppressing the decrease in on-current is improved. As a result, it is possible to suppress the decrease in on-current in the normal state and to improve the short-circuit tolerance.

From the viewpoint of promoting the flow of electrons around the bottom of the surface region 32 and suppressing the decrease in on-current in the normal state, the depth of the first surface region 32a is preferably smaller than the depth of the first body region 26a, and more preferably smaller than the depth of the first source region 30a.

From the viewpoint of suppressing the flow of electrons in a short-circuit state and improving the short-circuit tolerance, it is preferable that the first length (L1 in FIG. 1) of the first surface region 32a in the second direction is larger than the first distance (d1 in FIG. 3) between the first body region 26a and the second body region 26b.

From the viewpoint of suppressing the decrease in on-current in the normal state, it is preferable that the first length (L1 in FIG. 1) of the first surface region 32a in the second direction is equal to or less than twice the first distance (d1 in FIG. 3) between the first body region 26a and the second body region 26b.

From the viewpoint of suppressing the flow of electrons in a short-circuit state and improving the short-circuit tolerance, it is preferable that the first length (L1 in FIG. 3) of the first surface region 32a in the second direction is equal to or more than 20% of the second distance (d2 in FIG. 3) between the first JFET region 24x1 and the second surface region 32b.

From the viewpoint of suppressing the decrease in on-current in the normal state, it is preferable that the first length (L1 in FIG. 3) of the first surface region 32a in the second direction is equal to or less than 50% of the second distance (d2 in FIG. 3) between the first JFET region 24x1 and the second surface region 32b.

It is preferable that the p-type impurity concentration of a portion of the surface region 32 in contact with the gate insulating layer 16 is higher than the p-type impurity concentration of the first channel portion 26a1 of the first body region 26a. If the p-type impurity concentration of the surface region 32 is lower than the p-type impurity concentration of the first channel portion 26a1, when the MOSFET 100 is turned on, an inversion layer may be formed in the surface region 32 to cause electrons to flow, making it impossible to limit the path through which electrons flow due to the surface region 32.

As described above, according to the first embodiment, it is possible to realize a MOSFET with improved short-circuit tolerance by providing a surface region.

### Modification Example

A semiconductor device according to a modification example of the first embodiment is different from the semiconductor device according to the first embodiment in that the second silicon carbide region includes a fifth portion in contact with the gate insulating layer and provided in the first direction of the fifth silicon carbide region and the second conductive type impurity concentration of the fifth portion is higher than the second conductive type impurity concentration of the fourth portion.

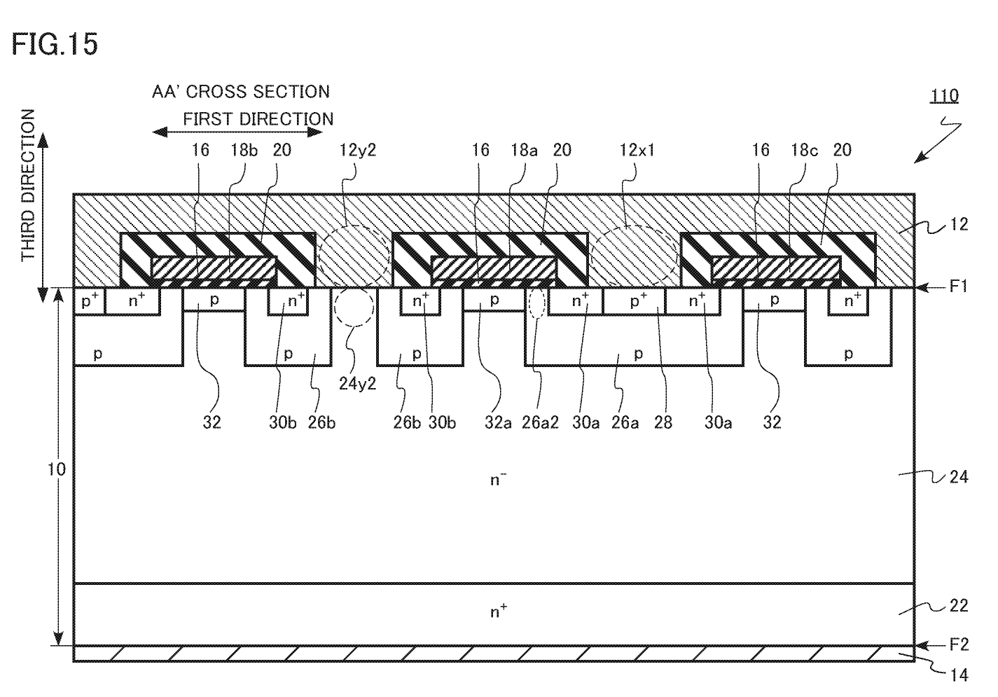

FIG. 15 is a schematic cross-sectional view of the semiconductor device according to the modification example of the first embodiment. FIG. 15 is a diagram corresponding to FIG. 1 in the first embodiment.

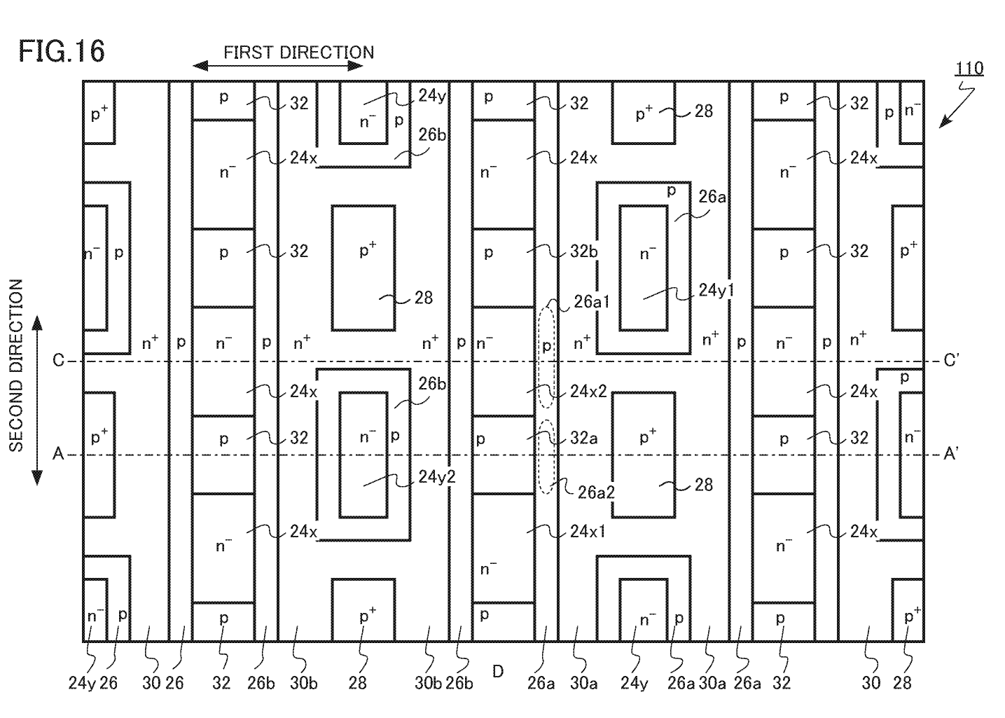

FIG. 16 is a schematic top view of the semiconductor device according to the modification example of the first embodiment. FIG. 16 is a diagram showing a pattern of a semiconductor region on the surface of a silicon carbide layer. FIG. 15 is a cross-sectional view taken along the line AA' of FIG. 16. FIG. 16 is a diagram corresponding to FIG. 3 in the first embodiment.

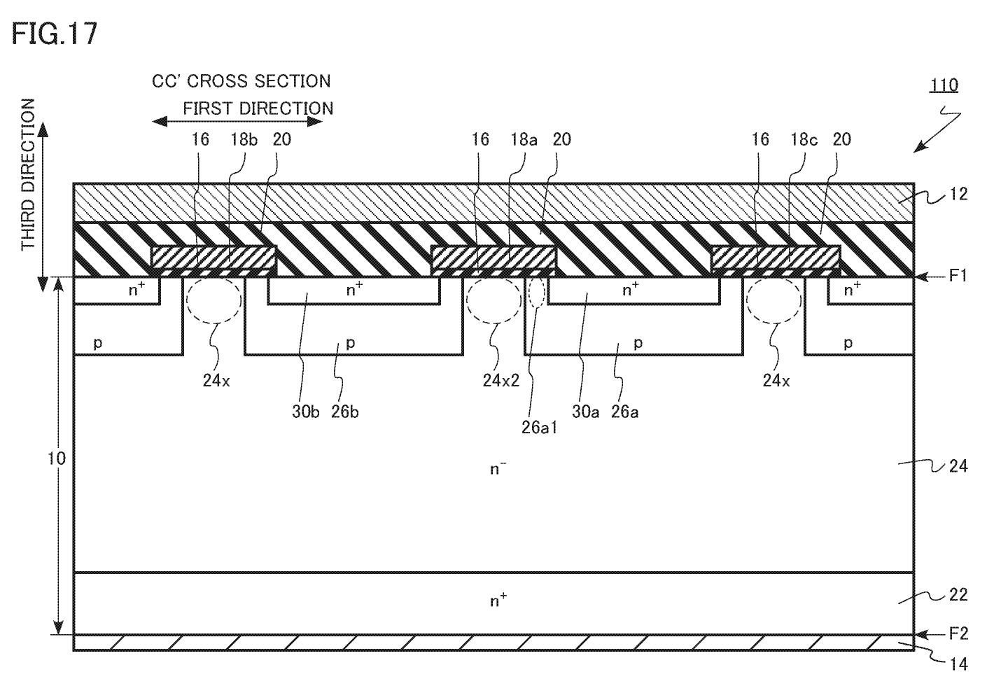

FIG. 17 is a schematic cross-sectional view of the semiconductor device according to the modification example of the first embodiment. FIG. 17 is a cross-sectional view taken along the line CC' of FIG. 16.

The first body region 26a includes a first channel portion 26a1 (fourth portion) and a second channel portion 26a2 (fifth portion).

The first cross section is a cross section that includes the first contact electrode portion 12x1 in contact with the first source region 30a of the source electrode 12 and is perpendicular to the first face F1 and parallel to the first direction. The AA' cross section shown in FIG. 15 is an example of the first cross section.

The third cross section is a cross section that includes the second JFET region 24x2 and is perpendicular to the first face F1 and parallel to the first direction. The CC' cross section shown in FIG. 17 is an example of the third cross section.

The first channel portion 26a1 is provided in the first direction of the second JFET region 24x2. The first channel portion 26a1 is provided between the second JFET region 24x2 and the first source region 30a. The first channel portion 26a1 is in contact with the gate insulating layer 16. The first channel portion 26a1 is included in the third cross section. In the first channel portion 26a1, a channel through which electrons flow is formed when the MOSFET 110 is turned on.

The second channel portion 26a2 is provided in the first direction of the first surface region 32a. The second channel portion 26a2 is provided between the first surface region 32a and the first source region 30a. The second channel portion 26a2 is in contact with the first surface region 32a. The second channel portion 26a2 is in contact with the gate insulating layer 16. The second channel portion 26a2 is included in the first cross section.

The p-type impurity concentration of the second channel portion 26a2 is higher than the p-type impurity concentration of the first channel portion 26a1.

By making the p-type impurity concentration of the second channel portion 26a2 higher than the p-type impurity concentration of the first channel portion 26a1, an inversion layer is less likely to be formed in the second channel portion 26a2 when the MOSFET 110 is turned on. In other words, when the MOSFET 110 is turned on, a channel through which electrons flow is less likely to be formed in the second channel portion 26a2.

When the MOSFET 110 is turned on, a channel through which electrons flow is not formed in the second channel portion 26a2 and accordingly, no electrons flow. This further limits the path through which electrons flow when the MOSFET 110 is turned on. Therefore, the short-circuit tolerance of the MOSFET 110 is improved.

As described above, according to the first embodiment and its modification example, a MOSFET with improved short-circuit tolerance is realized by providing a surface region.

### Second Embodiment

A semiconductor device according to a second embodiment is different from the semiconductor device according to the first embodiment in that a diode electrode portion is not provided in the first direction of the contact electrode portion but a different contact electrode portion is provided in the first direction of the contact electrode portion. Hereinafter, the description of a part of the content overlapping the first embodiment may be omitted.

The semiconductor device according to the second embodiment is a planar gate type vertical MOSFET 200 using silicon carbide. The MOSFET 200 according to the second embodiment includes an SBD as a built-in diode.

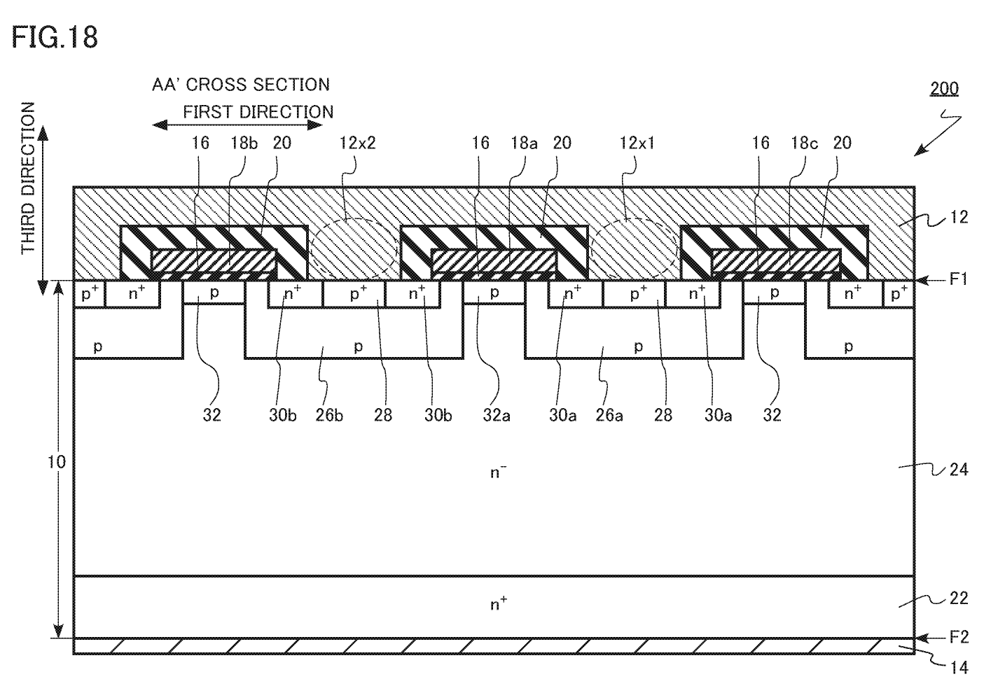

FIG. 18 is a schematic cross-sectional view of the semiconductor device according to the second embodiment.

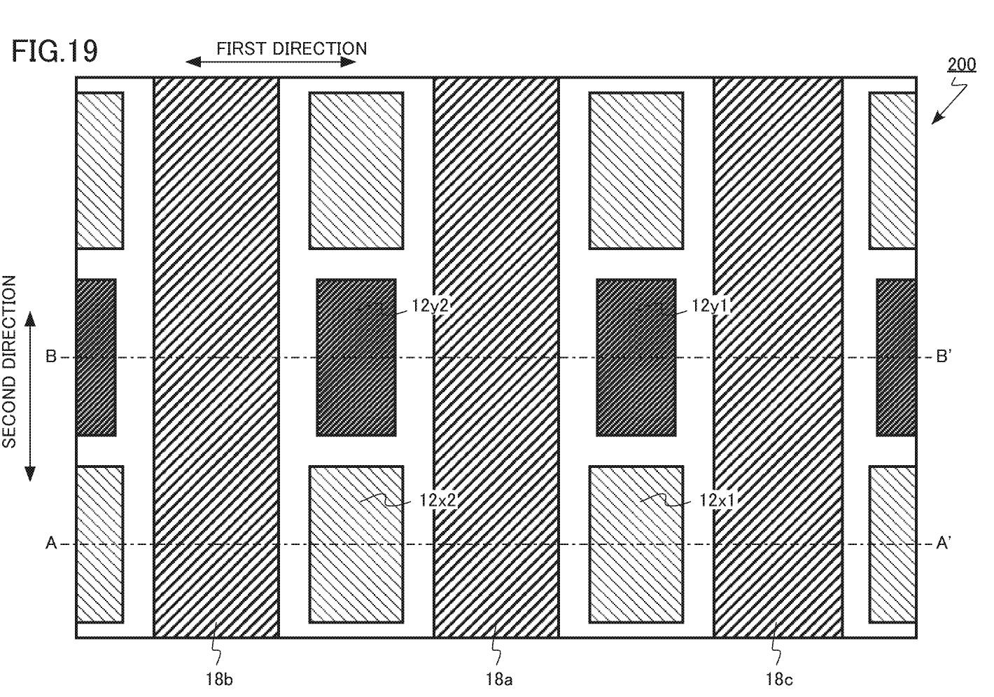

FIG. 19 is a schematic top view of the semiconductor device according to the second embodiment. FIG. 19 is a schematic diagram showing a pattern of a gate electrode and a source electrode on the top surface of a silicon carbide layer. FIG. 19 shows a pattern of a contact electrode portion and a diode electrode portion of the source electrode. FIG. 18 is a cross-sectional view taken along the line AA' of FIG. 19.

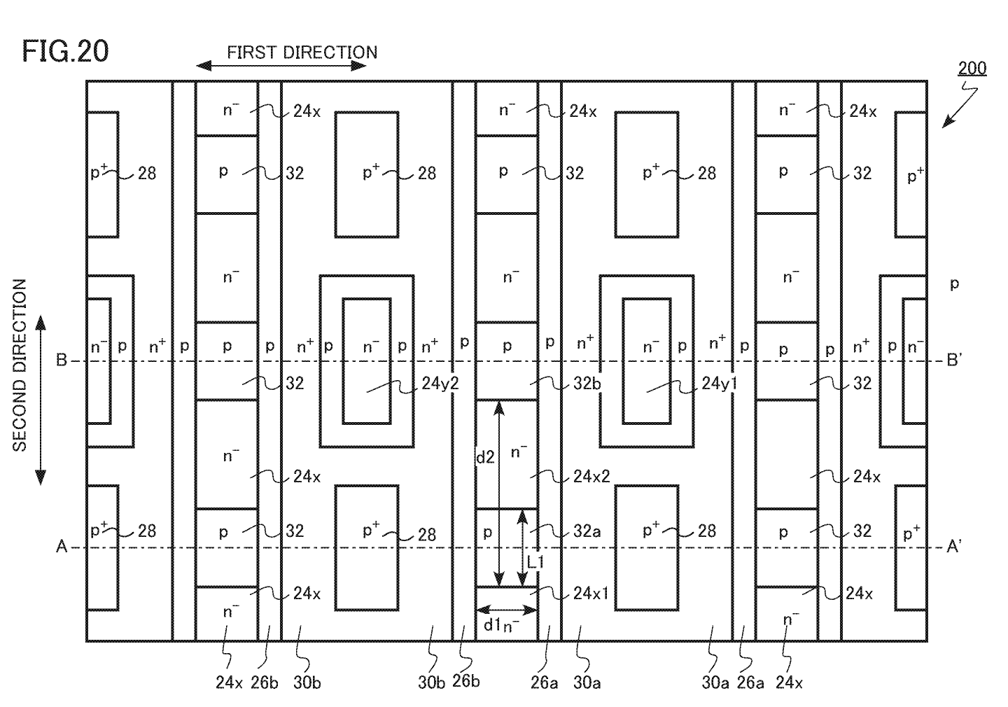

FIG. 20 is a schematic top view of the semiconductor device according to the second embodiment. FIG. 20 is a diagram showing a pattern of a semiconductor region on the surface of a silicon carbide layer. FIG. 18 is a cross-sectional view taken along the line AA' of FIG. 20.

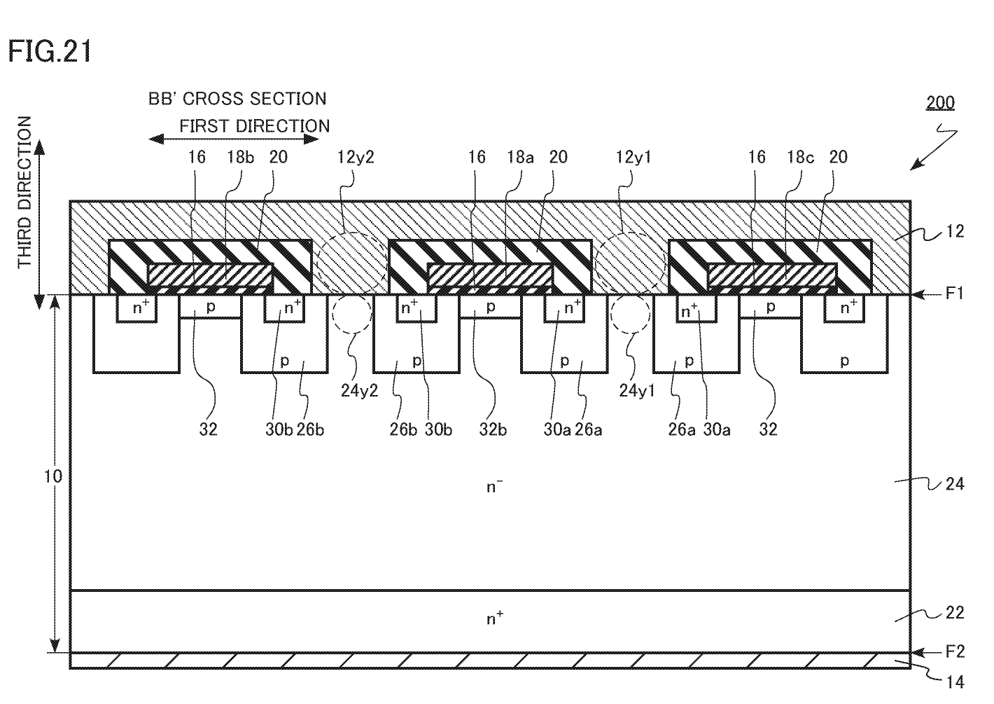

FIG. 21 is a schematic cross-sectional view of the semiconductor device according to the second embodiment. FIG. 21 is a cross-sectional view taken along the line BB' of FIGS. 19 and 20.

The AA' cross section shown in FIG. 18 is an example of the first cross section. The BB' cross section shown in FIG. 21 is an example of the second cross section.

The MOSFET 200 includes a silicon carbide layer 10, a source electrode 12 (first electrode), a drain electrode 14 (second electrode), a gate insulating layer 16, a gate electrode 18, and an interlayer insulating layer 20. The source electrode 12 includes a contact electrode portion 12x and a diode electrode portion 12y. The contact electrode portion 12x includes a first contact electrode portion 12x1 (first portion) and a second contact electrode portion 12x2. The diode electrode portion 12y includes a first diode electrode portion 12y1 (second portion) and a second diode electrode portion 12y2. The gate electrode 18 includes a first gate electrode 18a, a second gate electrode 18b, and a third gate electrode 18c.

The silicon carbide layer 10 includes an n⁺-type drain region 22, an n⁻-type drift region 24 (first silicon carbide region), a p-type body region 26, a p⁺-type body contact region 28, an n⁺-type source region 30, and a p-type surface region 32. The p-type body region 26 includes a first body region of p-type 26a (second silicon carbide region) and a second body region of p-type 26b (third silicon carbide region). The first body region of p-type 26a includes a first channel portion 26a1 (fourth portion). The n⁺-type source region 30 includes a first source region of n⁺-type 30a (fourth silicon carbide region) and a second source region of n⁺-type 30b. The p-type surface region 32 includes a first surface region of p-type 32a (fifth silicon carbide region) and a second surface region of p-type 32b (sixth silicon carbide region).

The drift region 24 includes a JFET region 24x. The drift region 24 includes a first JFET region 24x1 (first region) and a second JFET region 24x2 (second region).

The drift region 24 includes a JBS region 24y. The JBS region 24y includes a first JBS region 24y1 (third region) and a second JBS region 24y2.

A first length (L1 in FIG. 20) of the first surface region 32a in the second direction is, for example, larger than a first distance (d1 in FIG. 20) between the first body region 26a and the second body region 26b. The first length L1 is, for example, equal to or less than twice the first distance d1.

The first length (L1 in FIG. 20) of the first surface region 32a in the second direction is, for example, equal to or more than 20% and equal to or less than 50% of the second distance (d2 in FIG. 20) between the first JFET region 24x1 and the second surface region 32b.

The diode electrode portion 12y is provided between two gate electrodes 18. The diode electrode portion 12y is provided in the second direction of the contact electrode portion 12x.

The contact electrode portion 12x and the diode electrode portion 12y are alternately and repeatedly arranged between the same two gate electrodes 18 in the second direction.

The contact electrode portions 12x are repeatedly arranged in the first direction with the gate electrode 18 interposed therebetween. The diode electrode portions 12y are repeatedly arranged in the first direction with the gate electrode 18 interposed therebetween.

As described above, according to the second embodiment, as in the first embodiment, it is possible to realize a MOSFET with improved short-circuit tolerance by providing a surface region.

### Third Embodiment

A semiconductor device according to a third embodiment is different from the semiconductor device according to the first embodiment in that the semiconductor device according to the third embodiment does not include an SBD as a built-in diode. Hereinafter, the description of a part of the content overlapping the first embodiment may be omitted.

The semiconductor device according to the third embodiment is a planar gate type vertical MOSFET 300 using silicon carbide. The MOSFET 300 according to the third embodiment does not include an SBD as a built-in diode.

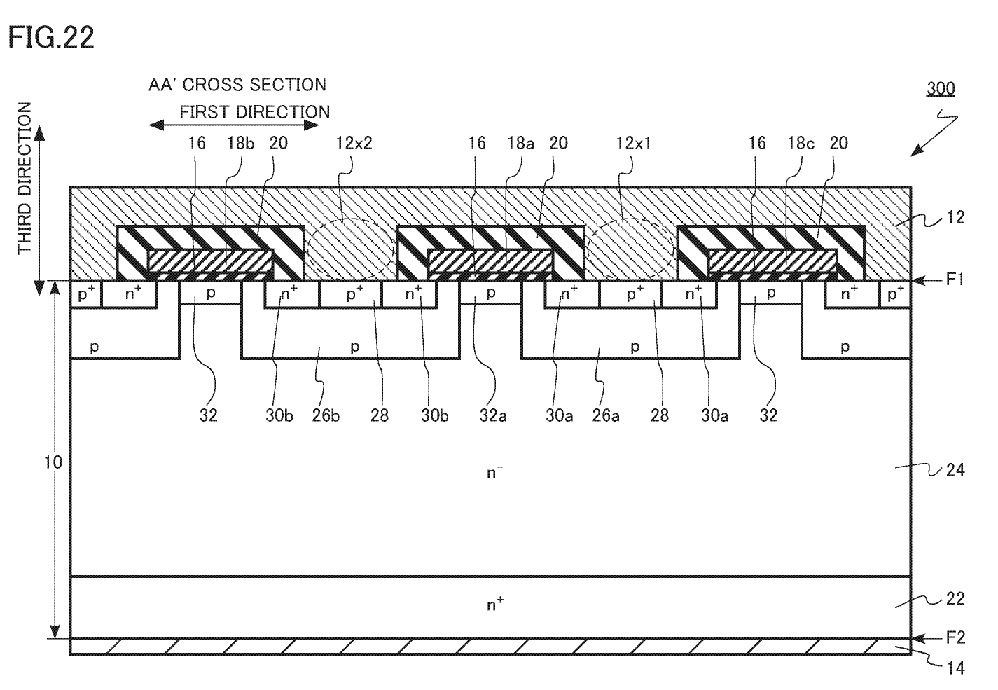

FIG. 22 is a schematic cross-sectional view of the semiconductor device according to the third embodiment.

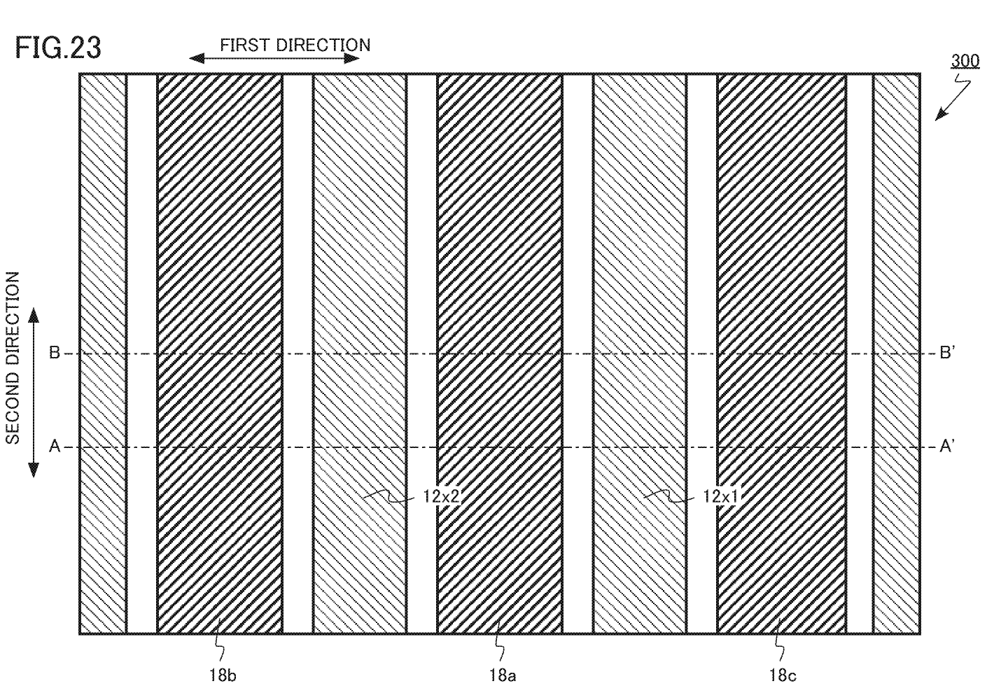

FIG. 23 is a schematic top view of the semiconductor device according to the third embodiment. FIG. 23 is a schematic diagram showing a pattern of a gate electrode and a source electrode on the top surface of a silicon carbide layer. FIG. 23 shows a pattern of a contact electrode portion of a source electrode. FIG. 22 is a cross-sectional view taken along the line AA' of FIG. 23.

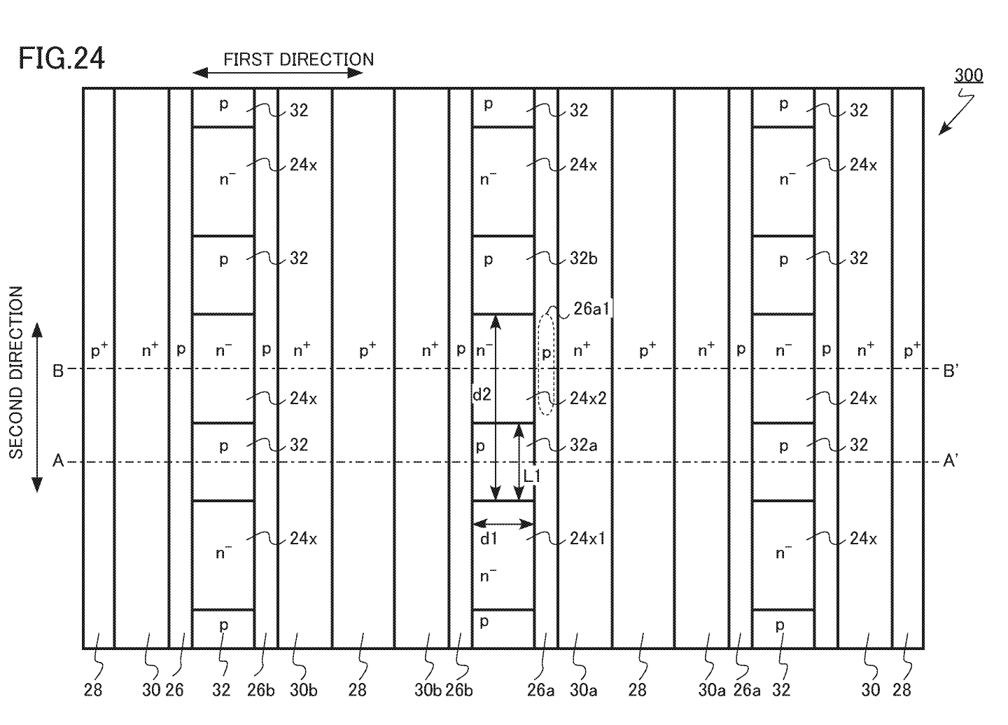

FIG. 24 is a schematic top view of the semiconductor device according to the third embodiment. FIG. 24 is a diagram showing a pattern of a semiconductor region on the surface of a silicon carbide layer. FIG. 22 is a cross-sectional view taken along the line AA' of FIG. 24.

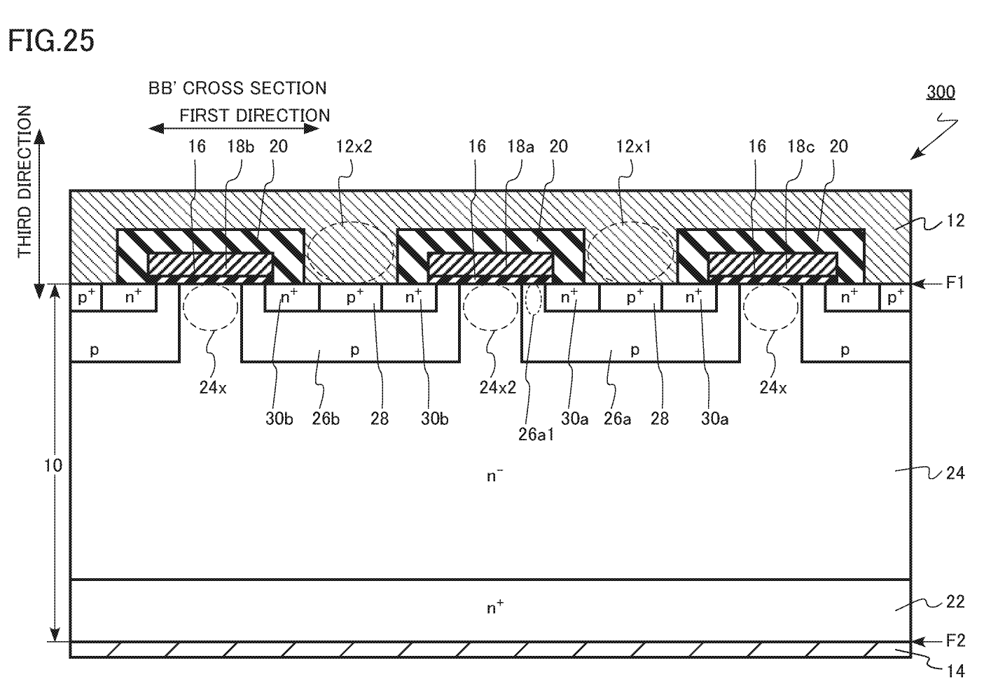

FIG. 25 is a schematic cross-sectional view of the semiconductor device according to the third embodiment. FIG. 25 is a cross-sectional view taken along the line BB' of FIGS. 23 and 24.

FIG. 22 is an example of the first cross section.

The MOSFET 300 includes a silicon carbide layer 10, a source electrode 12 (first electrode), a drain electrode 14 (second electrode), a gate insulating layer 16, a gate electrode 18, and an interlayer insulating layer 20. The source electrode 12 includes a contact electrode portion 12x. The contact electrode portion 12x includes a first contact electrode portion 12x1 (first portion) and a second contact electrode portion 12x2. The gate electrode 18 include a first gate electrode 18a, a second gate electrode 18b, and a third gate electrode 18c.

The silicon carbide layer 10 includes an n⁺-type drain region 22, an n⁻-type drift region 24 (first silicon carbide region), a p-type body region 26, a p⁺-type body contact region 28, an n⁺-type source region 30, and a p-type surface region 32. The p-type body region 26 includes a first body region of p-type 26a (second silicon carbide region) and a second body region of p-type 26b (third silicon carbide region). The first body region of p-type 26a includes a first channel portion 26a1 (fourth portion). The n⁺-type source region 30 includes a first source region of n⁺-type 30a (fourth silicon carbide region) and a second source region of n⁺-type 30b. The p-type surface region 32 includes a first surface region of p-type 32a (fifth silicon carbide region) and a second surface region of p-type 32b (sixth silicon carbide region).

The drift region 24 includes a JFET region 24x. The drift region 24 includes a first JFET region 24x1 (first region) and a second JFET region 24x2 (second region).

A first length (L1 in FIG. 24) of the first surface region 32a in the second direction is, for example, larger than a first distance (d1 in FIG. 24) between the first body region 26a and the second body region 26b. The first length L1 is, for example, equal to or less than twice the first distance d1.

The first length (L1 in FIG. 24) of the first surface region 32a in the second direction is, for example, equal to or more than 20% and equal to or less than 50% of the second distance (d2 in FIG. 24) between the first JFET region 24x1 and the second surface region 32b.

The contact electrode portion 12x extends in the second direction between the two gate electrodes 18. The contact electrode portions 12x are repeatedly arranged in the first direction with the gate electrode 18 interposed therebetween.

As described above, according to the third embodiment, as in the first embodiment, it is possible to realize a MOSFET with improved short-circuit tolerance by providing a surface region.

In the first to third embodiments, the case of 4H-SiC has been described as an example of the crystal structure of SiC. However, embodiments can also be applied to devices using SiC having other crystal structures, such as 6H-SiC and 3C-SiC. In addition, a face other than the (0001) face can also be applied as the surface of the silicon carbide layer 10.

In the first to third embodiments, the case where the first conductive type is n-type and the second conductive type is p-type has been described as an example. However, the first conductive type can be p-type and the second conductive type can be n-type.

In the first to third embodiments, aluminum (Al) has been exemplified as a p-type impurity, but boron (B) can also be used. In addition, although nitrogen (N) and phosphorus (P) have been exemplified as n-type impurities, arsenic (As), antimony (Sb), and the like can also be applied.

In the first to third embodiments, the MOSFET having a structure in which the gate electrode and the body region extend in one direction and the gate electrode and the body region are repeatedly arranged in a direction perpendicular to the extending direction has been described as an example. Embodiments can also be applied to MOSFETs having structures other than the above-described structure as long as the MOSFETs are planar gate type MOSFETs in which a drift region is provided between two body regions facing each other.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first electrode including a first portion;
a second electrode;
a silicon carbide layer provided between the first electrode and the second electrode, having a first face on a side of the first electrode and a second face on a side of the second electrode, and including:
a first silicon carbide region of a first conductive type including a first region in contact with the first face and a second region in contact with the first face;
a second silicon carbide region of a second conductive type provided between the first silicon carbide region and the first face;
a third silicon carbide region of the second conductive type provided between the first silicon carbide region and the first face and spaced from the second silicon carbide region in a first direction parallel to the first face, the first region and the second region being provided between the second silicon carbide region and the third silicon carbide region;
a fourth silicon carbide region of the first conductive type provided between the second silicon carbide region and the first face and in contact with the first portion; and
a fifth silicon carbide region of the second conductive type provided between the second silicon carbide region and the third silicon carbide region, in contact with the second silicon carbide region and the third silicon carbide region, provided between the first region and the second region, in contact with the first region and the second region, provided between the first silicon carbide region and the first face, in contact with the first face, and provided in the first direction of the first portion;
a first gate electrode provided on a side of the first face of the silicon carbide layer and facing the first region, the second region, the second silicon carbide region, the third silicon carbide region, and the fifth silicon carbide region on the first face; and
a gate insulating layer provided between the silicon carbide layer and the first gate electrode.

2. The semiconductor device according to claim 1,
wherein the second silicon carbide region and the third silicon carbide region extend in a second direction parallel to the first face and perpendicular to the first direction.

3. The semiconductor device according to claim 1,
wherein the first gate electrode extends in a second direction parallel to the first face and perpendicular to the first direction.

4. The semiconductor device according to claim 1,
wherein a depth of the fifth silicon carbide region is smaller than a depth of the second silicon carbide region.

5. The semiconductor device according to claim 1,
wherein a depth of the fifth silicon carbide region is smaller than a depth of the fourth silicon carbide region.

6. The semiconductor device according to claim 1,
wherein a first length of the fifth silicon carbide region in a second direction parallel to the first face and perpendicular to the first direction is larger than a first distance between the second silicon carbide region and the third silicon carbide region.

7. The semiconductor device according to claim 1,
wherein a first length of the fifth silicon carbide region in a second direction parallel to the first face and perpendicular to the first direction is equal to or less than twice a first distance between the second silicon carbide region and the third silicon carbide region.

8. The semiconductor device according to claim 1,
wherein the silicon carbide layer further includes a sixth silicon carbide region of the second conductive type provided between the second silicon carbide region and the third silicon carbide region, in contact with the second silicon carbide region and the third silicon carbide region, provided between the first silicon carbide region and the first face, in contact with the first face, and in contact with the second region, the second region being provided between the fifth silicon carbide region and the sixth silicon carbide region.

9. The semiconductor device according to claim 8,
wherein a first length of the fifth silicon carbide region in a second direction parallel to the first face and perpendicular to the first direction is equal to or more than 20% and equal to or less than 50% of a second distance between the first region and the sixth silicon carbide region.

10. The semiconductor device according to claim 8,
wherein the first silicon carbide region includes a third region in contact with the first face, provided in a second direction parallel to the first face and perpendicular to the first direction of the first portion, and in contact with the first electrode, and
the sixth silicon carbide region is provided in the first direction of the third region.

11. The semiconductor device according to claim 1,
wherein the second silicon carbide region includes a fourth portion in contact with the gate insulating layer and provided in the first direction of the second region, and
a second conductive type impurity concentration of a portion of the fifth silicon carbide region in contact with the gate insulating layer is higher than a second conductive type impurity concentration of the fourth portion.

12. The semiconductor device according to claim 11,
wherein the second silicon carbide region includes a fifth portion in contact with the gate insulating layer and provided in the first direction of the fifth silicon carbide region, and
a second conductive type impurity concentration of the fifth portion is higher than a second conductive type impurity concentration of the fourth portion.
